(19) United States
(12) Patent Application Publication
(10) Pub. No.: US 2023/0411291 A1
(43) Pub. Date: Dec. 21, 2023

(54) INTEGRATED CIRCUIT DEVICE AND METHOD FOR FABRICATING THE SAME

(71) Applicant: TAIWAN SEMICONDUCTOR MANUFACTURING COMPANY, LTD., Hsinchu (TW)

(72) Inventor: Jhon Jhy LIAW, Hsinchu County (TW)

(73) Assignee: TAIWAN SEMICONDUCTOR MANUFACTURING COMPANY, LTD., Hsinchu (TW)

(21) Appl. No.: 17/746,434

(22) Filed: May 17, 2022

(51) Int. Cl. H01L 23/528; H01L 27/092; H01L 29/06; H01L 29/417; H01L 29/423; H01L 29/45; H01L 29/786; H01L 21/285; H01L 29/66

(52) U.S. Cl. CPC H01L 23/5286; H01L 27/092; H01L 29/0665; H01L 29/41733; H01L 29/66742; H01L 29/45; H01L 29/78618; H01L 29/78696; H01L 21/28518; H01L 29/42392

(57) ABSTRACT

A semiconductor device includes a substrate, a dielectric fin, a gate, and a high-k dielectric layer. The dielectric fin is above the substrate and extending along a first direction. The gate is above the substrate and extends in a second direction that intersects the first direction. The high-k dielectric layer is vertically above the dielectric fin. The gate is over a sidewall and a bottom surface of the high-k dielectric layer.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-12F illustrate layouts and cross-sectional views of an integrated circuit structure at intermediate stages of fabrication process according to some embodiments of the present disclosure.

FIG. 13 is a cross-sectional views of an integrated circuit chip according to some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

As scales of the transistors decreases, backend metal layers have been touched the limitation in both resistance and capacitance. So the performance improvement of logic circuits can't only rely on the device boost, but also needed to concern about metal conductors RC delay as well as power conductors IR drop. These effects will slow down the cell speed or impact the scaling ratio. GAA transistors provide more channel width with least area than conventional planar transistor or fin field effect transistors (FinFET), and also allow channel length continues scaling. So backend-of-line (BEOL) routing efficiency becomes the bottleneck of circuits scaling in GAA era. In standard cell routing, the Vdd and Vss power routing occupied many routing resources and therefore impact the cell scaling as well as cell performance (due to RC delay or IR drop).

Embodiments of the present disclosure are related to integrated circuit structures and methods of forming the same, and more particularly to transistors with frond-side source node connection and back-side drain node connection. Source node is connected to front-side's contact and power conductor for contact resistance reduction, thereby reducing the IR drop in power transmission. Drain node is connected to back-side contact and signal conductors for capacitance reduction, thereby reducing the RC delay in signal transmission. Through the configuration, the metal routing and the SID connection setting may improve both cell/device density and performance.

It is also noted that the present disclosure presents embodiments in the form of multi-gate transistors. Multi-gate transistors include those transistors whose gate structures are formed on at least two-sides of a channel region. Specific examples may be presented and referred to herein as FINFET, on account of their fin-like structure. Also presented herein are embodiments of a type of multi-gate transistor referred to as a gate-all-around (GAA) device. A GAA device includes any device that has its gate structure, or portion thereof, formed on 4-sides of a channel region (e.g., surrounding a portion of a channel region). Devices presented herein also include embodiments that have channel regions disposed in nanosheet channel(s), nanowire channel(s), and/or other suitable channel configuration. Presented herein are embodiments of devices that may have one or more channel regions (e.g., nanosheets) associated with a single, contiguous gate structure.

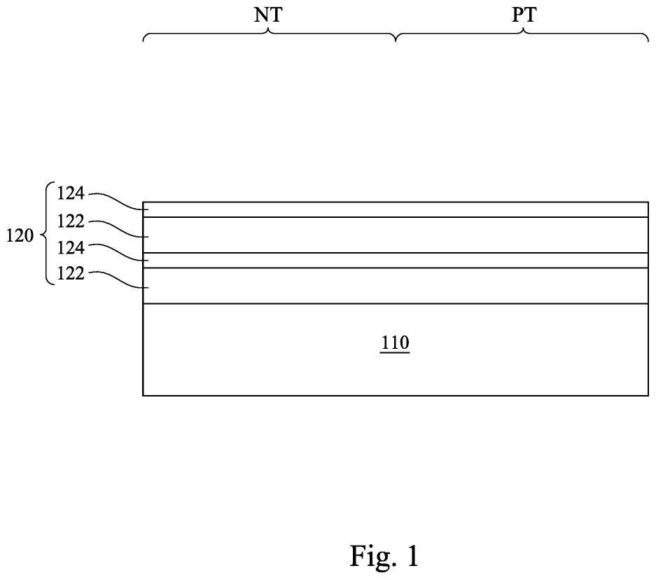

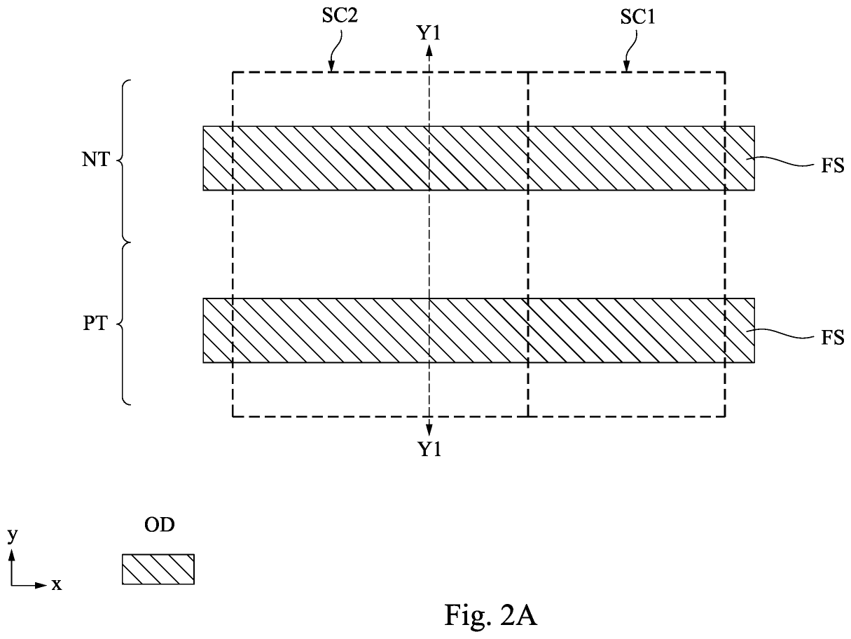

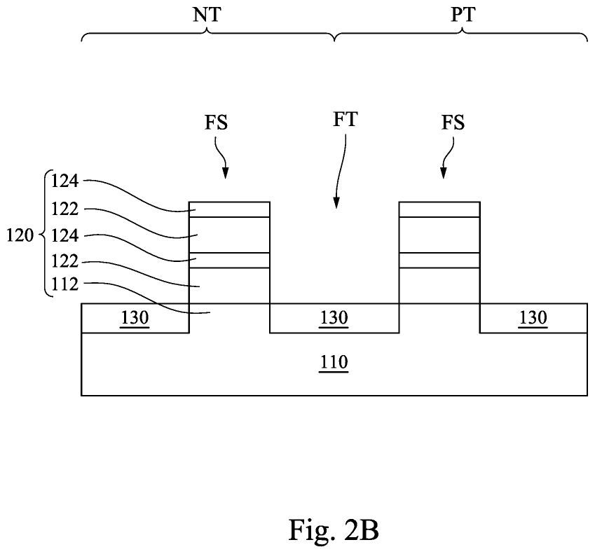

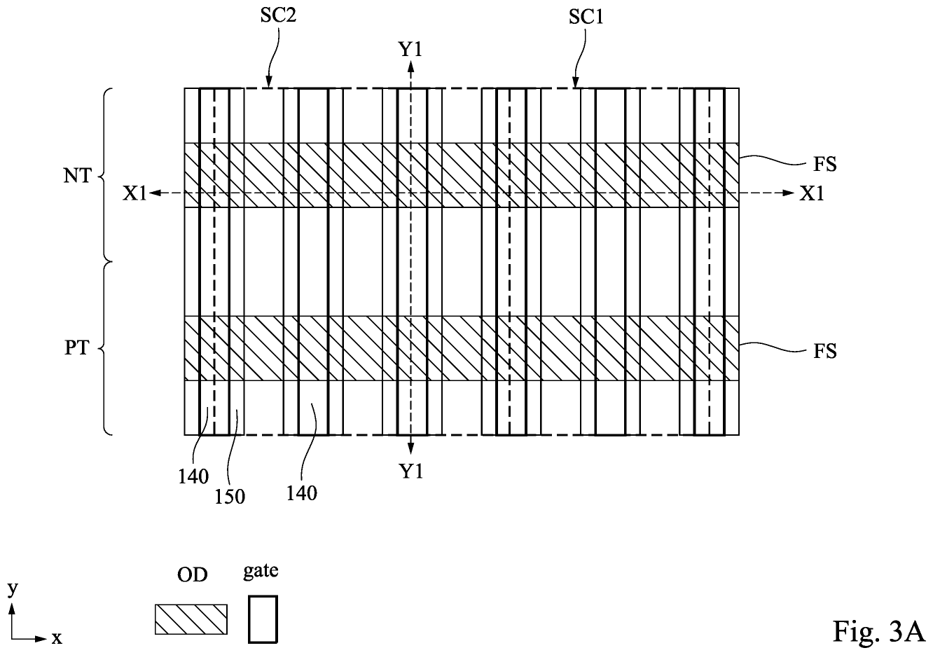

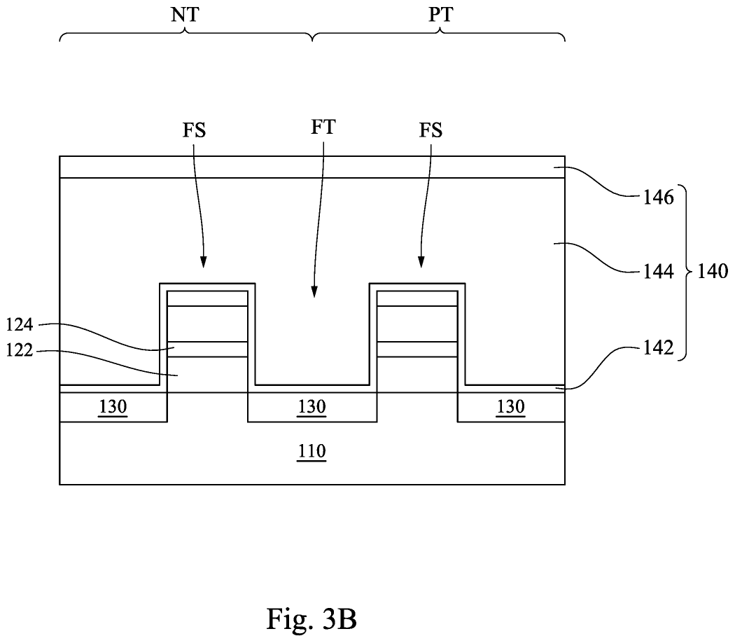

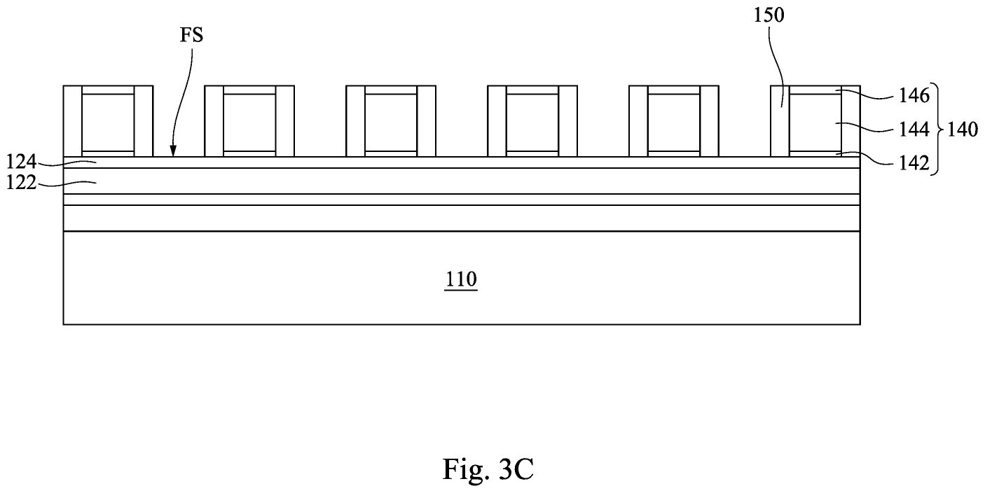

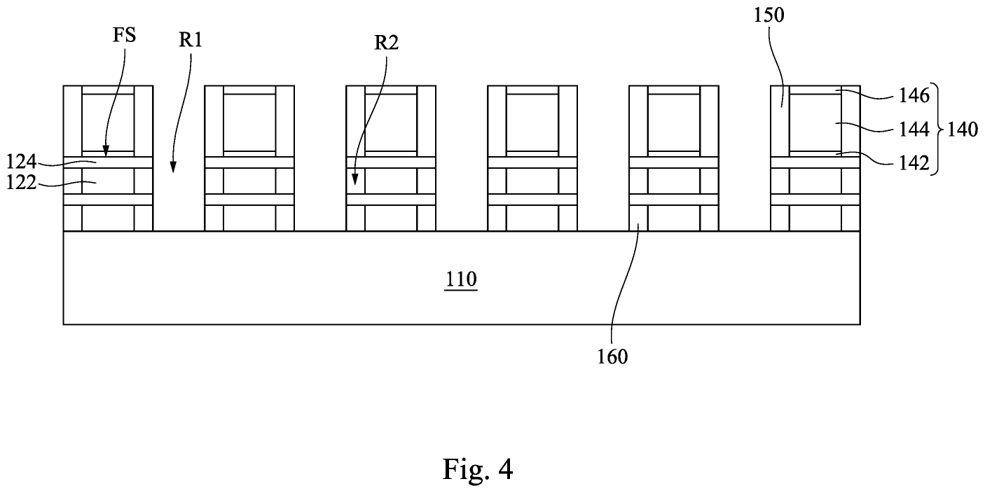

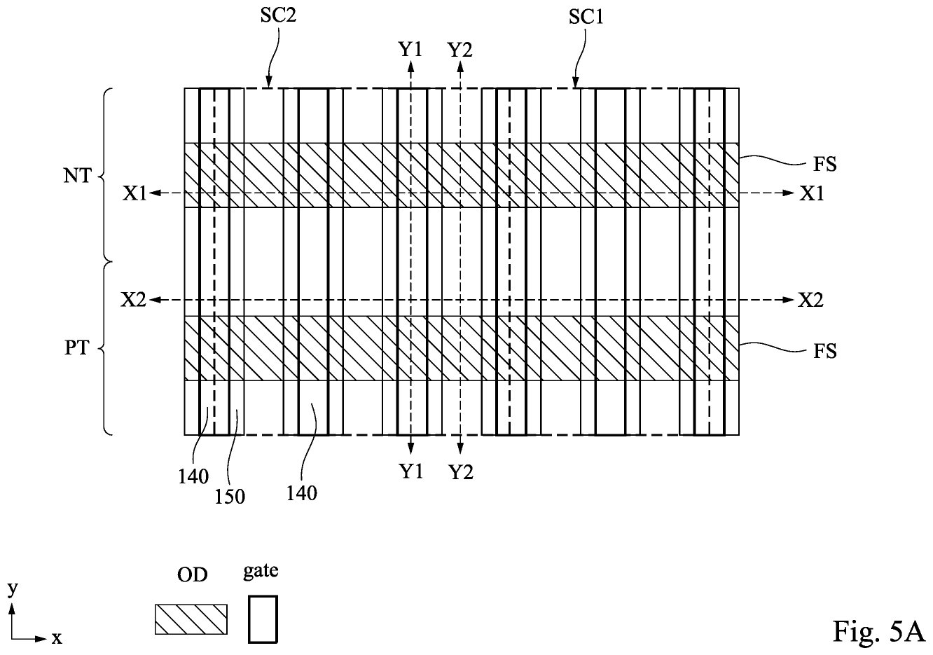

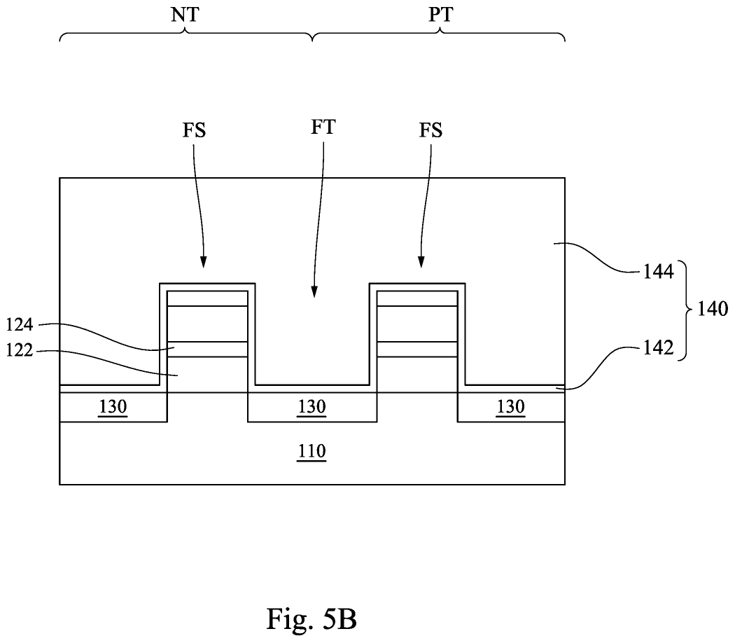

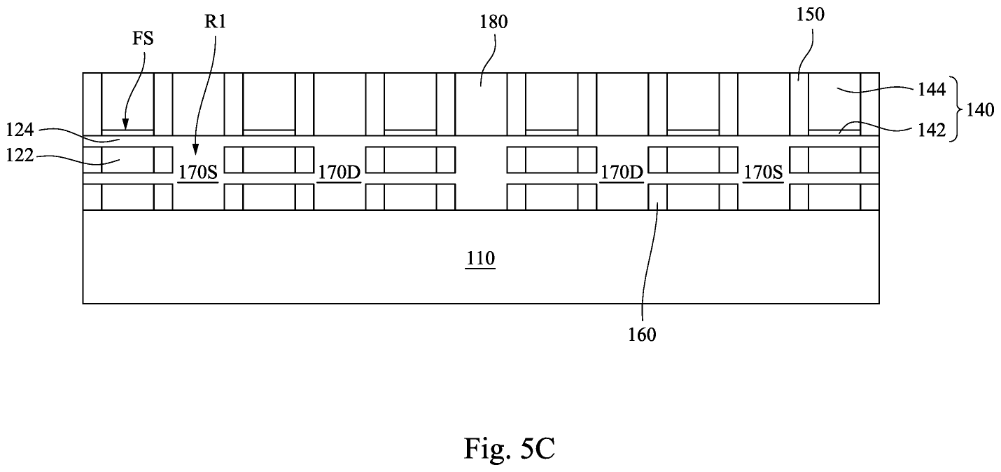

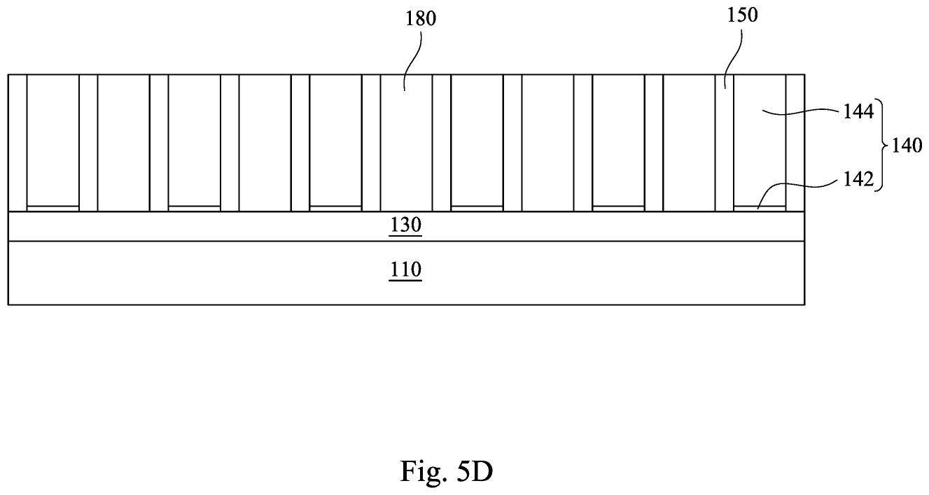

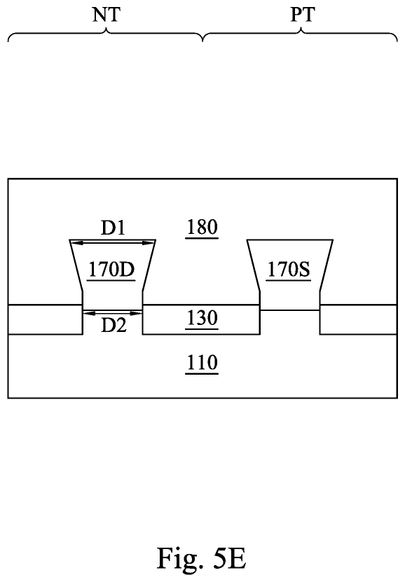

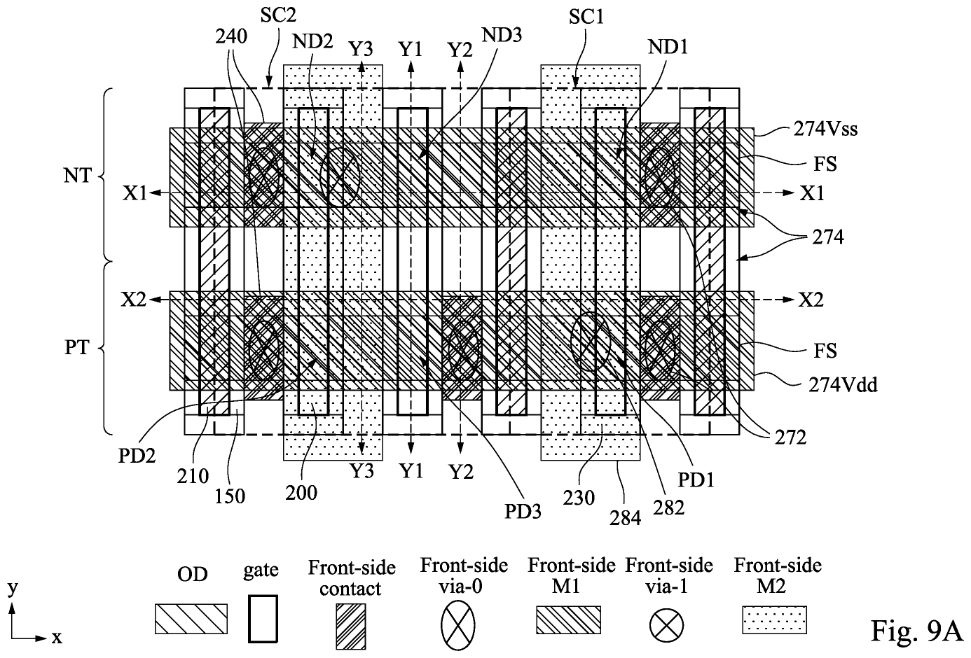

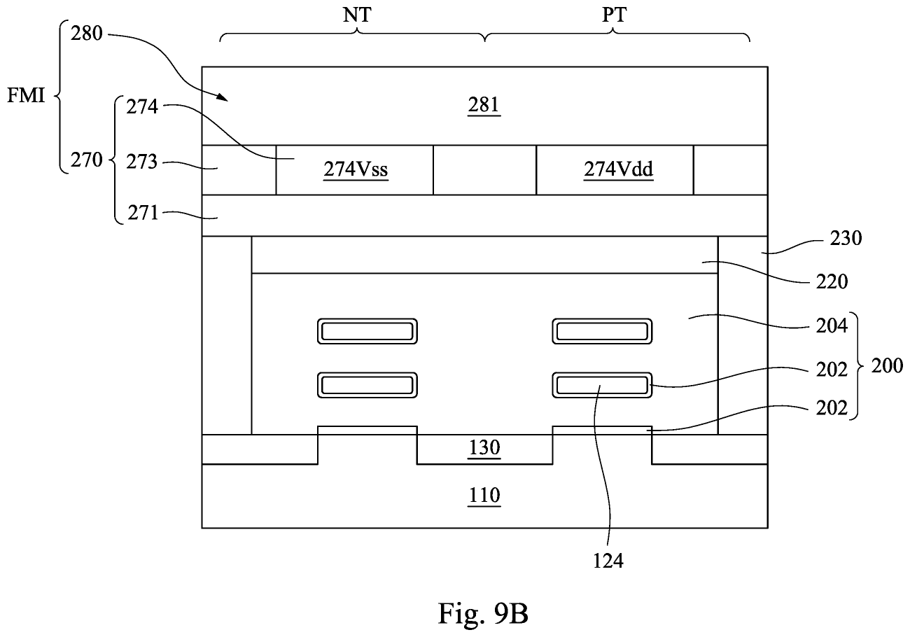

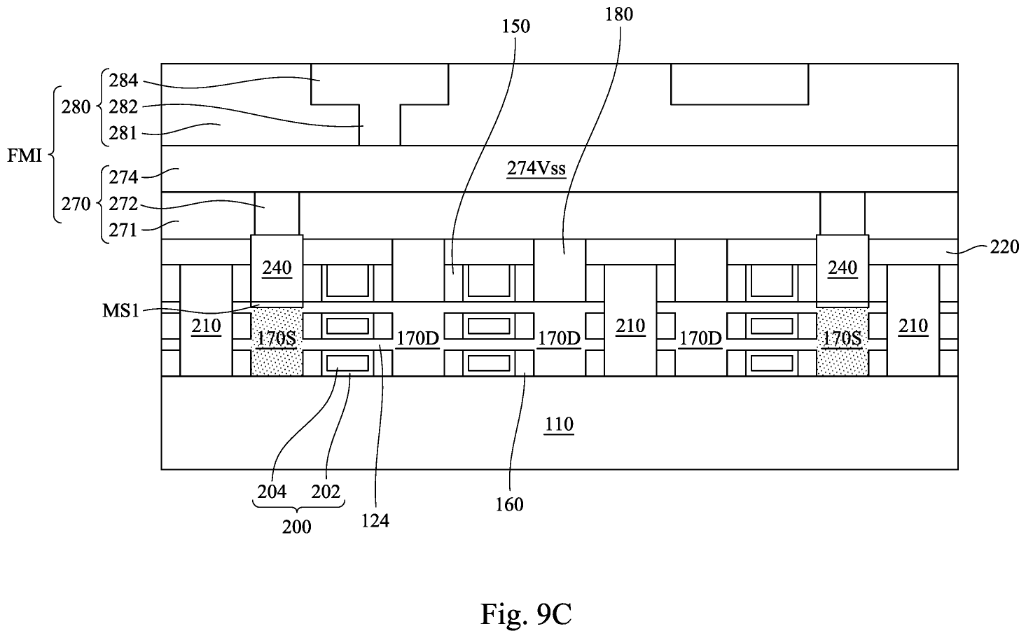

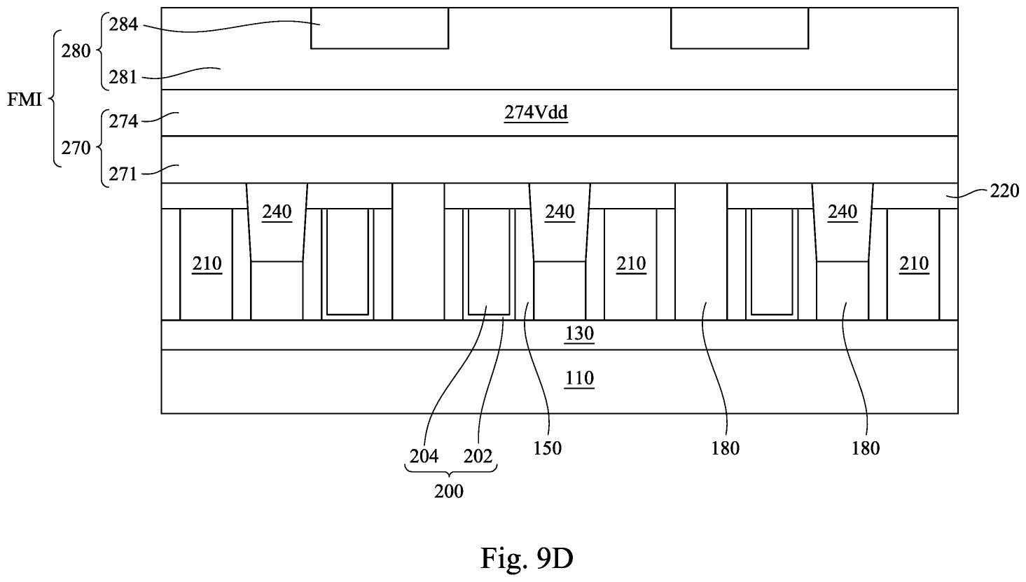

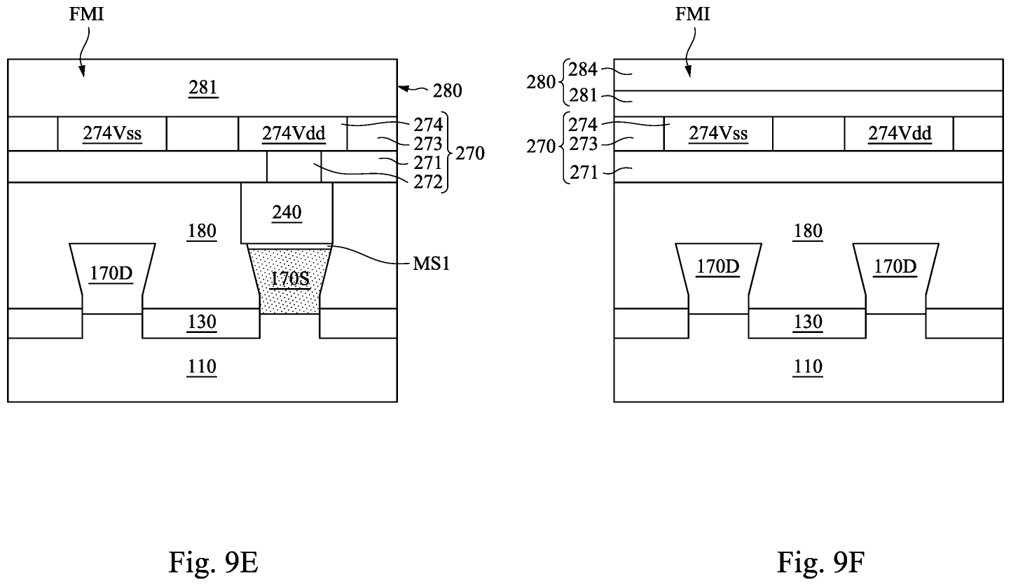

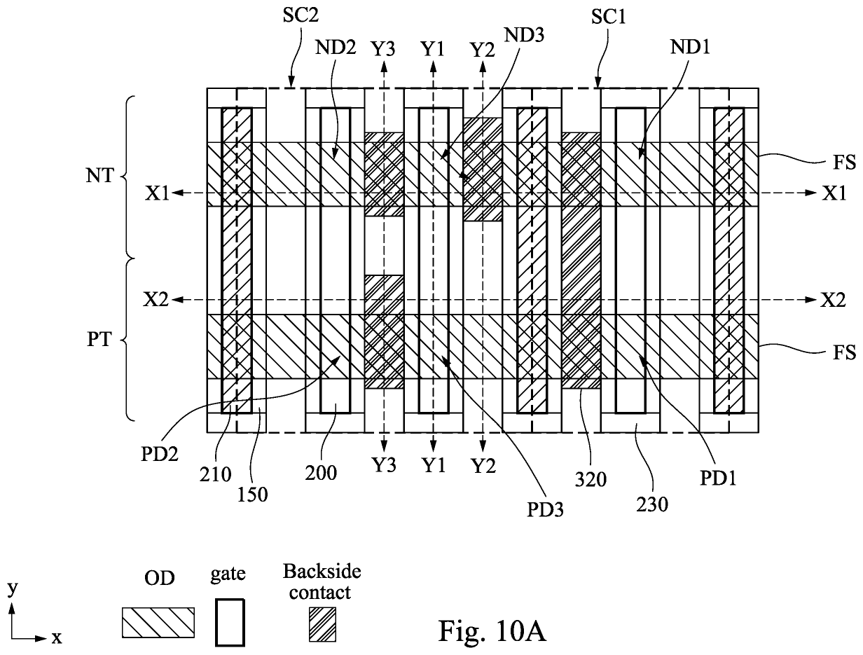

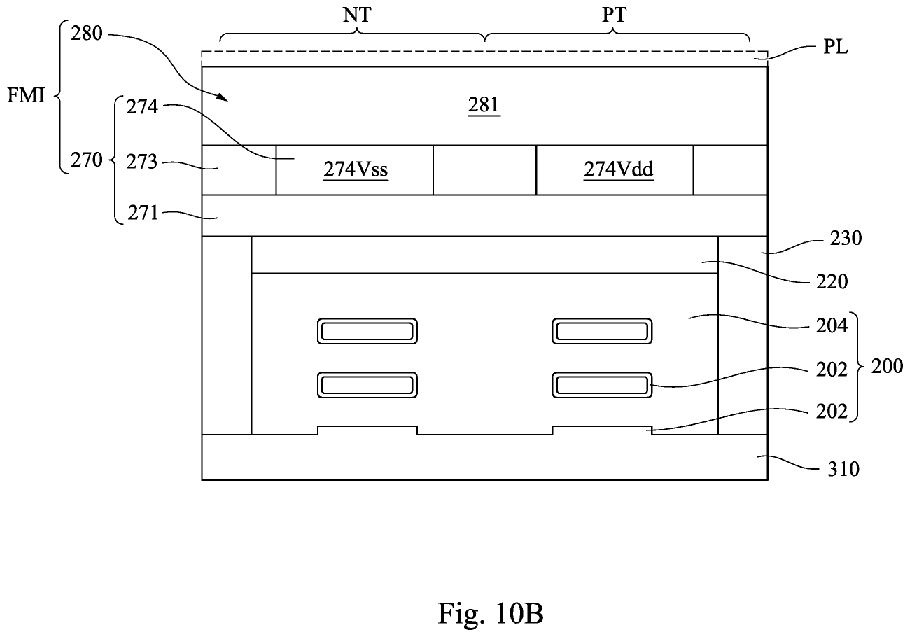

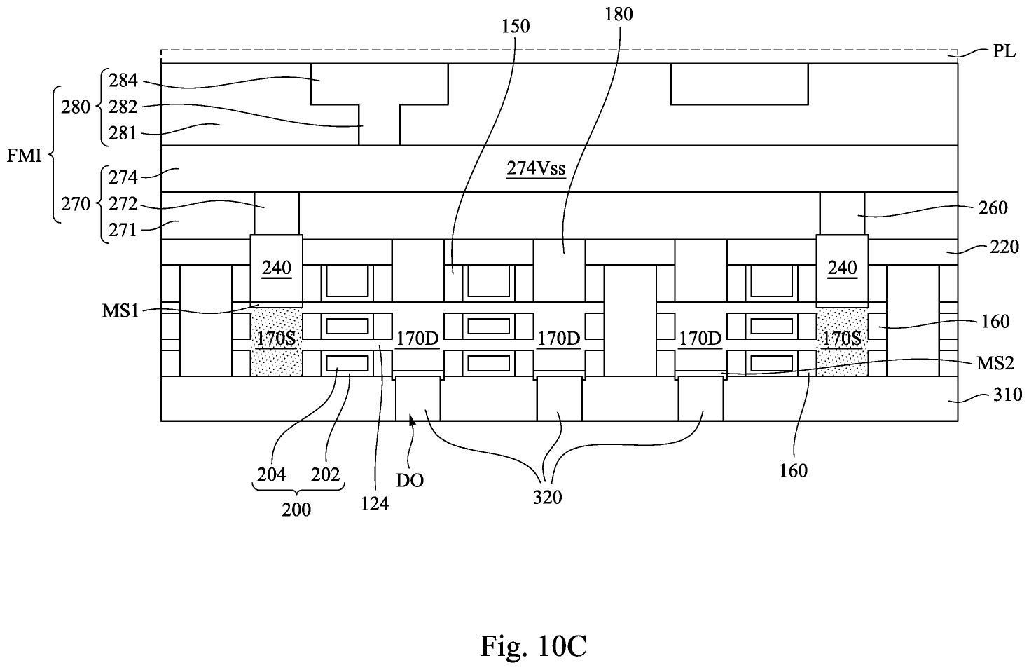

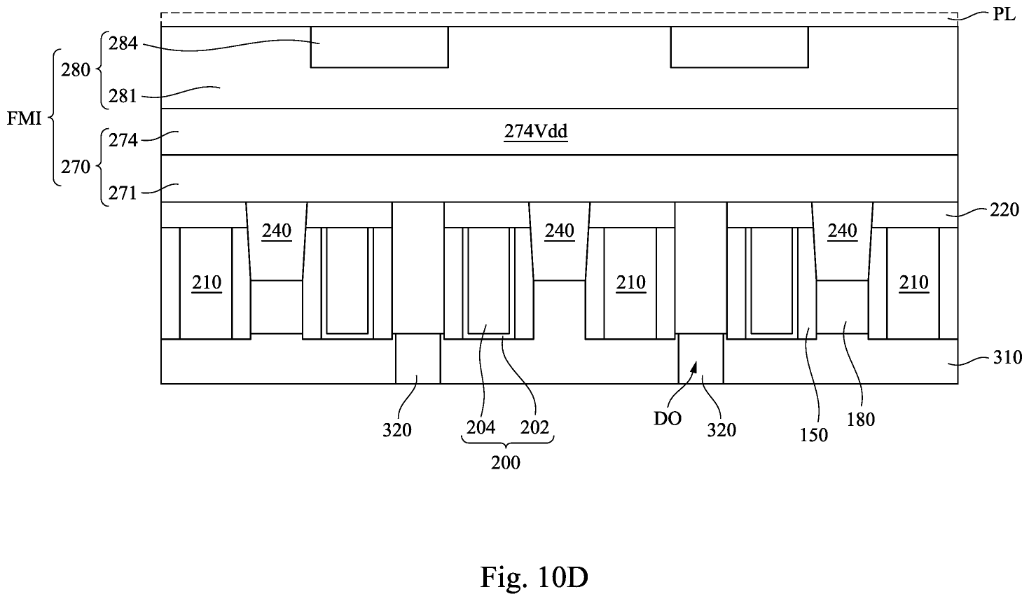

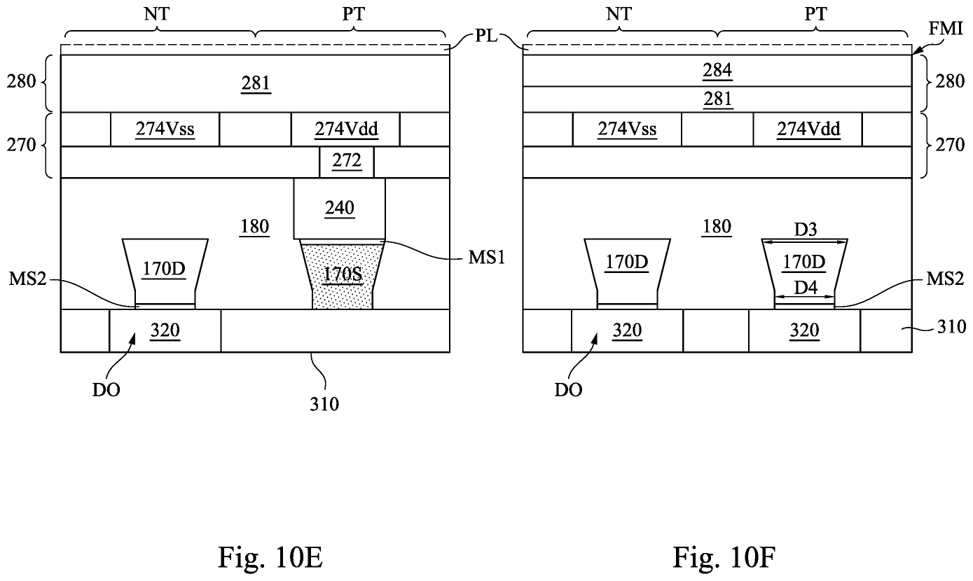

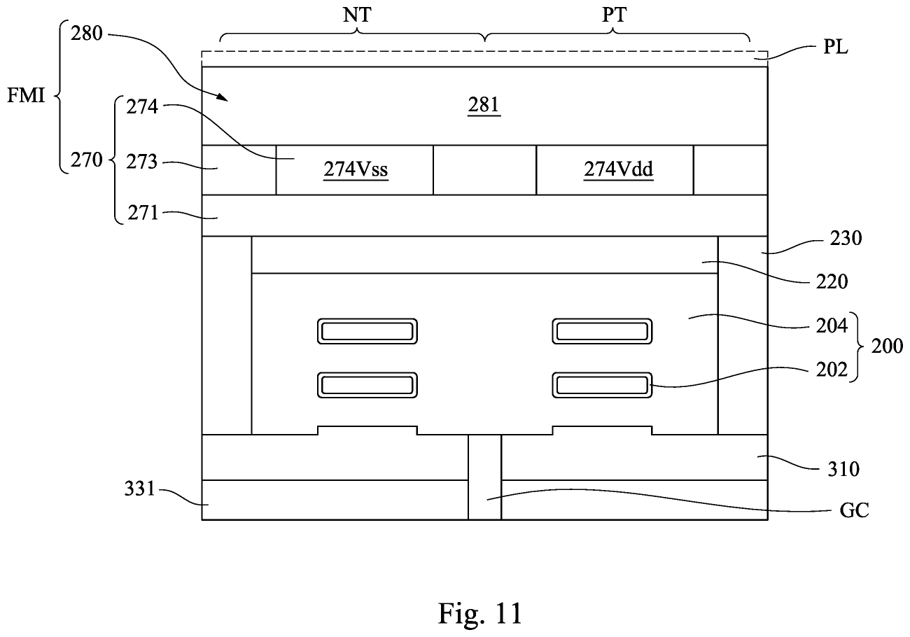

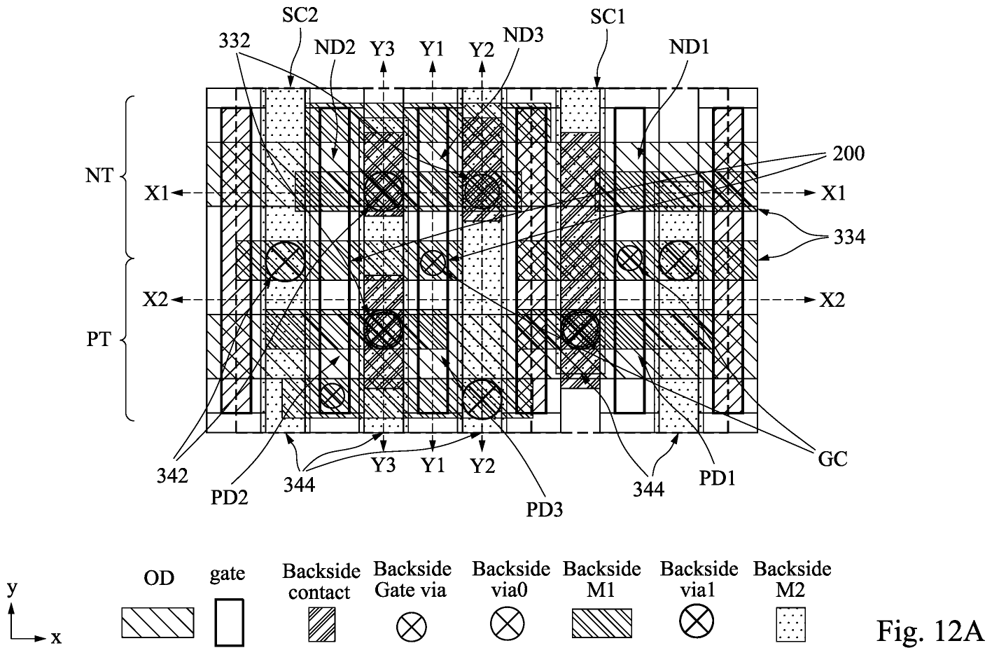

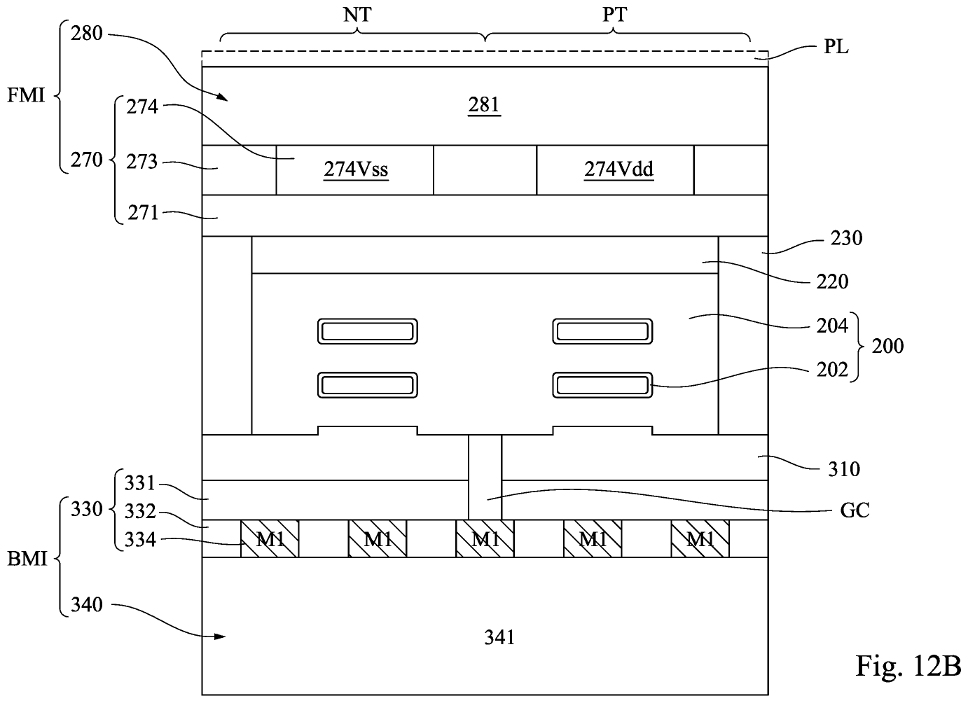

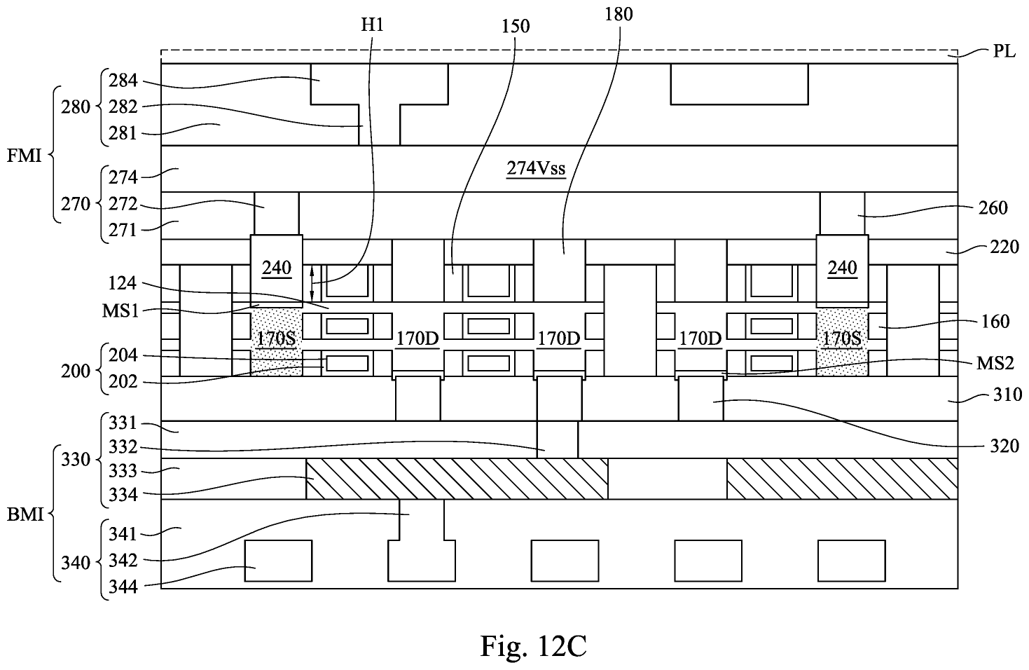

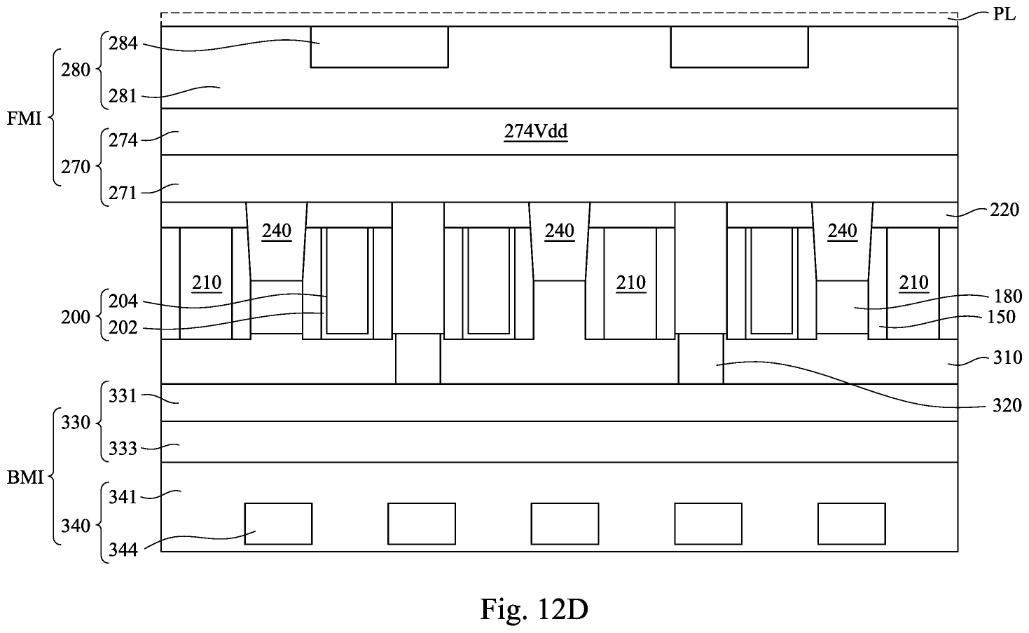

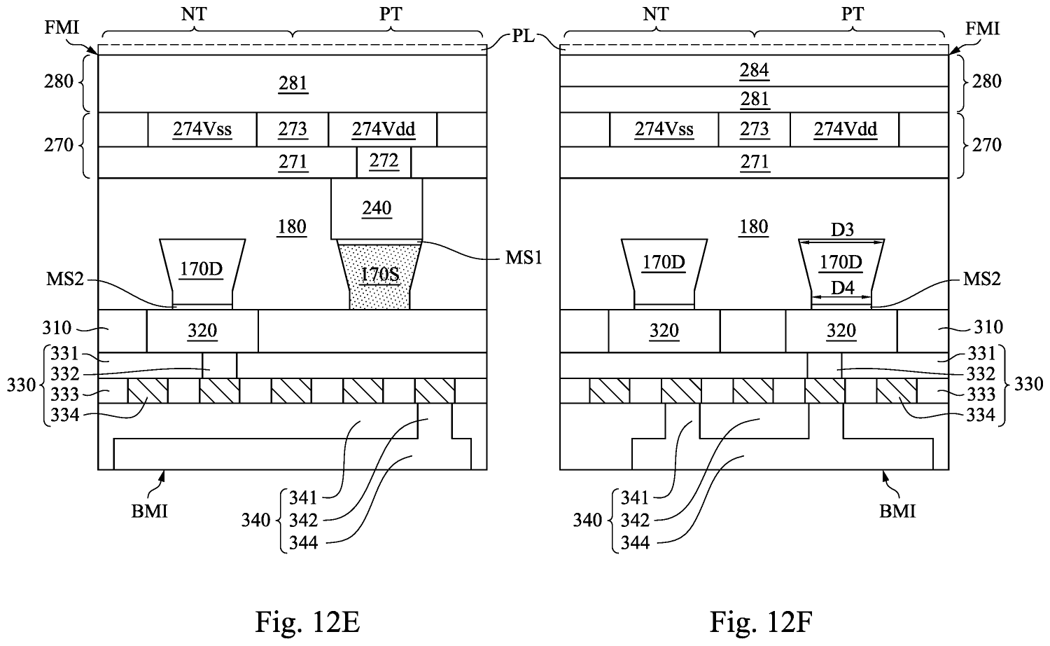

FIGS. 1-12F illustrate layouts and cross-sectional views of an integrated circuit structure at intermediate stages of fabrication process according to some embodiments of the present disclosure. FIGS. 2A, 3A, 5A-10A, and 12A are layouts of the integrated circuit structure at the intermediate stages of fabrication process according to some embodiments of the present disclosure. FIGS. 2A, 3A, and 5A-9A show front-side layouts, and FIGS. 10A and 12A show back-side layouts, while all the front-side layouts and back-side layouts are illustrated as being viewed from top/front side. In the layouts of FIGS. 2A, 3A, 5A-10A, and 12A, boundaries of standard cells SC1 and SC2 are shown, in which the standard cells SC1 corresponds to an inverter, and the cells SC2 corresponds to a NAND. FIGS. 2B, 3B, 5B-10B, and 12B illustrate cross-sectional views taken along line Y1-Y1 in FIGS. 2A, 3A, 5A-10A, and 12A, respectively. FIG. 11 illustrates a cross-sectional view taken along the same line as the line Y1-Y1. FIGS. 3C, 5C-6C, 8C-IOC, and 12C illustrate cross-sectional views taken along line X1-X1 in FIGS. 3A, 5A-6A, 8A-10A, and 12A respectively. FIG. 4 illustrates a cross-sectional view taken along the same line as the line X1-X1. FIGS. 5D, 6D, 8D-10D, and 12D illustrate cross-sectional views taken along line X2-X2 in FIGS. 5A, 6A, 8A-10A, and 12A, respectively. FIGS. 5E, 8E-10E, and 12E illustrate cross-sectional views taken along line Y2-Y2 in FIGS. 5A, 8A-10A, and 12A, respectively. FIGS. 9F, 10F, 12F illustrate cross-sectional views taken along line Y3-Y3 in FIGS. 9A, 10A, 12A, respectively.

As with the other method embodiments and exemplary devices discussed herein, it is understood that parts of the integrated circuit structure may be fabricated by a CMOS technology process flow, and thus some processes are only briefly described herein. Further, the exemplary integrated circuit structure may include various other devices and features, such as other types of devices such as additional transistors, bipolar junction transistors, resistors, capacitors, inductors, diodes, fuses, static random access memory (SRAM) and/or other logic circuits, etc., but is simplified for a better understanding of the concepts of the present disclosure. In some embodiments, the exemplary integrated circuit structure includes a plurality of semiconductor devices (e.g., transistors), including PFETs, NFETs, etc., which may be interconnected.

FIG. 1 shows an initial structure. The initial structure includes a substrate 110. In some embodiments, the substrate 110 may include silicon (Si). Alternatively, the substrate 110 may include germanium (Ge), silicon germanium (SiGe), a III-V material (e.g., GaAs, GaP, GaAsP, AlInAs, AlGaAs, GaInAs, InAs, GaInP, InP, InSb, and/or GaInAsP; or a combination thereof) or other appropriate semiconductor materials. In some embodiments, the substrate 110 may include a semiconductor-on-insulator (SOI) structure. For example, the substrate 110 may include a bulk semiconductor substrate, a buried dielectric layer over the bulk substrate, and a semiconductor layer over the buried dielectric layer. The substrate 110 may include a region NT where n-type devices (e.g., NMOSFET) are to be formed and a region PT where p-type devices (e.g., PMOSFET) are to be formed.

An epitaxial stack 120 is formed over the substrate 110. The epitaxial stack 120 includes epitaxial layers 122 of a first composition interposed by epitaxial layers 124 of a second composition. The first and second compositions can be different. In some embodiments, the epitaxial layers 122 are SiGe and the epitaxial layers 124 are silicon (Si). However, other embodiments are possible including those that provide for a first composition and a second composition having different oxidation rates and/or etch selectivity. In some embodiments, the epitaxial layers 122 include SiGe and where the epitaxial layers 124 include Si, the Si oxidation rate of the epitaxial layers 124 is less than the SiGe oxidation rate of the epitaxial layers 122.

The epitaxial layers 124 or portions thereof may form nanosheet channel(s) of the multi-gate transistor. The term nanosheet is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including for example a cylindrical in shape or substantially rectangular cross-section. The use of the epitaxial layers 124 to define a channel or channels of a device is further discussed below. It is noted that two layers of the epitaxial layers 122 and two layers of the epitaxial layers 124 are alternately arranged as illustrated in FIG. 1. It can be appreciated that any number of epitaxial layers can be formed in the epitaxial stack 120; the number of layers depending on the desired number of channels regions for the transistor. In some embodiments, the number of epitaxial layers 124 is between 2 and 10.

In some embodiments, the epitaxial layers 122 may be substantially uniform in thickness, and the epitaxial layers 124 of the stack are substantially uniform in thickness. As described in more detail below, the epitaxial layers 124 may serve as channel region(s) for a subsequently-formed multi-gate device and the thickness is chosen based on device performance considerations. The epitaxial layers 122 in channel regions(s) may eventually be removed and serve to define a vertical distance between adjacent channel region(s) for a subsequently-formed multi-gate device and the thickness is chosen based on device performance considerations. Accordingly, the epitaxial layers 122 may also be referred to as sacrificial layers, and epitaxial layers 124 may also be referred to as channel layers.

By way of example, epitaxial growth of the layers of the stack 120 may be performed by a molecular beam epitaxy (MBE) process, a metalorganic chemical vapor deposition (MOCVD) process, and/or other suitable epitaxial growth processes. In some embodiments, the epitaxially grown layers such as, the epitaxial layers 124 include the same material as the substrate 110. In some embodiments, the epitaxially grown layers 122 and 124 include a different material than the substrate 110. As stated above, in at least some examples, the epitaxial layers 122 include an epitaxially grown silicon germanium (SiGe) layer and the epitaxial layers 124 include an epitaxially grown silicon (Si) layer. Alternatively, in some embodiments, either of the epitaxial layers 122 and 124 may include other materials such as germanium, a compound semiconductor such as silicon carbide, gallium arsenide, gallium phosphide, indium phosphide, indium arsenide, and/or indium antimonide, an alloy semiconductor such as SiGe, GaAsP, AlInAs, AIGaAs, InGaAs, GaInP, and/or GaInAsP, or combinations thereof. As discussed, the materials of the epitaxial layers 122 and 124 may be chosen based on providing differing oxidation and/or etching selectivity properties. In some embodiments, the epitaxial layers 122 and 124 are substantially dopant-free (i.e., having an extrinsic dopant concentration from about 0 cm⁻³ to about 1×10¹⁸ cm⁻³), where for example, no intentional doping is performed during the epitaxial growth process.

Reference is made to FIGS. 2A and 2B. The epitaxial stack 120 and the substrate 110 are patterned, thereby forming plural fins FS. The fins FS may extend along direction X. The patterning may include suitable lithography process and etching processes. The lithography process (e.g., photolithography or e-beam lithography) may include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. In some embodiments, the etching process may include dry etching (e.g., reactive ion etching), wet etching, and/or other etching methods. In some embodiments, masks are formed over the epitaxial stack 120 by the photolithography process. The masks are used to protect regions of the substrate 110 and the epitaxial stack 120, while etching processes form trenches FT in unprotected regions through the epitaxial stack 120 and into the substrate 110, thereby leaving the plurality of extending fins FS.

In some alternative embodiments, the fins FS may be fabricated using suitable processes including double-patterning or multi-patterning processes. The double-patterning or multi-patterning processes combine photolithography and self-aligned processes, allowing patterns to be created that have, for example, pitches smaller than what is otherwise obtainable using a single, direct photolithography process. For example, in some embodiments, a sacrificial layer is formed over a substrate and patterned using a photolithography process. Spacers are formed alongside the patterned sacrificial layer using a self-aligned process. The sacrificial layer is then removed, and the remaining spacers, or mandrels, may then be used to pattern the fins FS by etching initial epitaxial stack 120. The etching process can include dry etching, wet etching, reactive ion etching (RIE), and/or other suitable processes.

Numerous other embodiments of methods to form the fins on the substrate may also be used including, for example, defining the fin region (e.g., by mask or isolation regions) and epitaxially growing the epitaxial stack 120 in the form of the fins FS. In various embodiments, each of the fins FS includes a base portion 112 patterned from the semiconductor substrate 110 and portions of each of the epitaxial layers 122 and 124 of the epitaxial stack 120.

Isolation structures 130 are formed in the trenches FT between the fins FS. The isolation structures 130 may be referred to as shallow trench isolation (STI) structures. By way of example and not limitation, a dielectric layer is first deposited over the substrate 110, filling the trenches FT with the dielectric material. In some embodiments, the dielectric layer may include silicon oxide, silicon nitride, silicon oxynitride, fluorine-doped silicate glass (FSG), a low-k dielectric, combinations thereof, and/or other suitable materials. In various examples, the dielectric layer may be deposited by a CVD process, a sub-atmospheric CVD (SACVD) process, a flowable CVD process, an ALD process, a physical vapor deposition (PVD) process, and/or other suitable processes. In some embodiments, the dielectric layer may include a multi-layer structure, for example, having one or more liner layers. In some embodiments, after deposition of the dielectric layer, the deposited dielectric material is thinned and planarized, for example by a chemical mechanical polishing (CMP) process.

In the layouts, regions between the isolation structures 130 are indicated as oxide-defined (OD) regions, which correspond to the fins FS. The isolation (or STI) structures 130 are recessed in an etch back process, such that the OD regions (e.g., fins FS) has exposed sidewall extending above the isolation structure 130. In some embodiments, the recessing process may include a dry etching process, a wet etching process, and/or a combination thereof. In some embodiments, a recessing depth is controlled (e.g., by controlling an etching time) so as to result in a target height of the exposed upper portion of the fins FS. In some embodiments, the target height for STI recessing is in a range from about 30 nanometers to about 80 nanometers. The target height may expose sidewalls of the OD regions (e.g., fins FS). In the illustrated embodiments, the target height exposes each of the epitaxial layers 122 and 124 of the epitaxial stack 120 in the fins FS.

Reference is made to FIGS. 3A-3C. A dummy gate dielectric layer 142 is then conformally deposited in the trenches FT and over the isolation structures 130. In some embodiments, the dummy gate dielectric layer 142 may include SiO₂, silicon nitride, a high-k dielectric material and/or other suitable material. In various examples, the dummy gate dielectric layer 142 may be deposited by a CVD process, a subatmospheric CVD (SACVD) process, a flowable CVD process, an ALD process, a PVD process, or other suitable process. By way of example, the dummy gate dielectric layer 142 may be used to prevent damages to the fins FS by subsequent processes (e.g., subsequent formation of the dummy gate structures).

Dummy gate structures 140 are formed in accordance with some embodiments of the present disclosure. The dummy gate structures 140 may extend along the direction Y intersecting the direction X that the fins FS extend along. For example, the direction Y is orthogonal to the direction X. In some embodiments, the dummy gate structures 140 each include the dummy gate dielectric layer 142, a dummy gate electrode layer 144 and a hard mask 146. In some embodiments, the dummy gate structures 260 are formed by various process steps such as layer deposition, patterning, etching, as well as other suitable processing steps. Exemplary layer deposition processes include CVD (including both low-pressure CVD and plasma-enhanced CVD), PVD, ALD, thermal oxidation, e-beam evaporation, or other suitable deposition techniques, or combinations thereof. In forming the gate structures for example, the patterning process includes a lithography process (e.g., photolithography or e-beam lithography) which may further include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. In some embodiments, the etching process may include dry etching (e.g., RIE etching), wet etching, and/or other etching methods.

In some embodiments, the dummy gate electrode layer 144 may include polycrystalline silicon (polysilicon). In some embodiments, the hard mask 146 includes an oxide layer such as a pad oxide layer that may include SiO₂, and a nitride layer such as a pad nitride layer that may include Si₃N₄ and/or silicon oxynitride. In some embodiments, after patterning the dummy gate electrode layer 144, exposed portions of the dummy gate dielectric layer 142 not covered under the patterned dummy gate electrode layer 144 are removed from source/drain regions of the fins FS. The etch process may include a wet etch, a dry etch, and/or a combination thereof. The etch process is chosen to selectively etch the dummy gate dielectric layer 142 without substantially etching the fins FS, the dummy gate electrode layer 144 and the hard mask 146.

In some embodiments, gate spacers 150 are formed on sidewalls of the dummy gate structures 140. The gate spacers 150 may include a dielectric material such as SiO₂, Si₃N₄, carbon doped oxide, nitrogen doped oxide, porous oxide, or the combination thereof. The gate spacers 150 may include multiple dielectric materials. In some embodiments, the gate spacers 150 may further include air gaps. In some embodiments of formation of the gate spacers 150, a spacer material layer is first deposited over the substrate 110. The spacer material layer may be a conformal layer that is subsequently etched to form gate sidewall spacers on sidewalls of the dummy gate structures 140. In the illustrated embodiments, a spacer material layer is disposed conformally on top and sidewalls of the dummy gate structures 260. By way of example, the spacer material layer may be formed by depositing a dielectric material over the gate structures 140 using processes such as, CVD process, a subatmospheric CVD (SACVD) process, a flowable CVD process, an ALD process, a PVD process, or other suitable process. An anisotropic etching process is then performed on the deposited spacer material layer to expose portions of the fins FS not covered by the dummy gate structures 140 (e.g., in source/drain regions of the fins FS denoted as “S” and “D”). Portions of the spacer material layer directly above the dummy gate structures 140 may be completely removed by this anisotropic etching process. Portions of the spacer material layer on sidewalls of the dummy gate structures 140 may remain, forming gate sidewall spacers, which are denoted as the gate spacers 150, for the sake of simplicity. In some embodiments, a thickness of the gate spacers 150 may be in a range from about 4 nanometers to about 120 nanometers. The gate spacers 150 serve to isolate metal gates from source contacts formed in subsequent processing.

Reference is made to FIG. 4. Exposed portions of the semiconductor fins FS that extend laterally beyond the gate spacers 150 (e.g., in source/drain regions SID of the fins FS) are etched by using, for example, an anisotropic etching process that uses the dummy gate structures 140 and the gate spacers 150 as an etch mask, resulting in recesses R1 into the semiconductor fins FS and between corresponding dummy gate structures 140. In some embodiments, the recesses R1 extends through the channel regions to the substrate 110 for exposing the sacrificial layers 122 and channel layers 124. After the anisotropic etching, end surfaces of the sacrificial layers 122 and channel layers 124 are substantially aligned with respective outermost sidewalls of the gate spacers 150, due to the anisotropic etching. In some embodiments, the anisotropic etching may be performed by a dry chemical etch with a plasma source and a reaction gas. The plasma source may be an inductively coupled plasma (ICR) source, a transformer coupled plasma (TCP) source, an electron cyclotron resonance (ECR) source or the like, and the reaction gas may be, for example, a fluorine-based gas (such as SF₆, CH₂F₂, CH₃F, CHF₃, or the like), chloride-based gas (e.g., Cl₂), hydrogen bromide gas (HBr), oxygen gas (O₂), the like, or combinations thereof.

The sacrificial layers 122 may be laterally or horizontally recessed by using suitable etch techniques, resulting in lateral recesses R₂ each vertically between corresponding channel layers 124. This step may be performed by using a selective etching process. By way of example and not limitation, the sacrificial layers 122 are SiGe and the channel layers 124 are silicon allowing for the selective etching of the sacrificial layers 122. In some embodiments, the selective wet etching includes an APM etch (e.g., ammonia hydroxide-hydrogen peroxide-water mixture) that etches SiGe at a faster etch rate than it etches Si. In some embodiments, the selective etching includes SiGe oxidation followed by a SiGeOₓ removal. For example, the oxidation may be provided by O₃ clean and then SiGeOₓ removed by an etchant such as NH₄OH that selectively etches SiGeOₓ at a faster etch rate than it etches Si. Moreover, because oxidation rate of Si is much lower than oxidation rate of SiGe, the channel layers 124 remain substantially intact during laterally recessing the sacrificial layers 122. As a result, the channel layers 124 laterally extend past opposite end surfaces of the sacrificial layers 122.

After the sacrificial layers 122 have been laterally recessed, inner spacers 160 are formed in the recesses R2 left by the lateral etching of the sacrificial layers 122. The inner spacers 160 may have a higher k value (or dielectric constant) than that of the gate spacers. For example, the inner spacers 160 includes a suitable dielectric material, such as SiO₂, Si₃N₄, SiON, SiOC, SiOCN, the like, or the combination thereof. In some embodiments, the inner spacers 160 may further include air gaps. Formation of the inner spacers 160 may include depositing an inner spacer material layer is formed to fill the recesses R2. The inner spacer material layer may be deposited by a suitable deposition method, such as ALD. After the deposition of the inner spacer material layer, an anisotropic etching process may be performed to trim the deposited inner spacer material, such that only portions of the deposited inner spacer material that fill the recesses left by the lateral etching of the sacrificial layers 122 are left. After the trimming process, the remaining portions of the deposited inner spacer material are denoted as inner spacers 160. In some embodiments, a thickness of the inner spacers 160 may be comparable to that of the gate spacers 150. For example, a thickness of the inner spacers 160 may be in a range from about 4 nanometers to about 120 nanometers. The inner spacers 160 serve to isolate metal gates from source/drain epitaxial structures formed in subsequent processing.

Reference is made to FIGS. 5A-5E. Source/drain epitaxial structures 170S/170D are formed in the recesses R1 in the fins FS. In greater detail, the source epitaxial structure 170S is formed in recessed source regions of the fin FS, and drain epitaxial structure 170D is formed in recessed drain regions of the fin FS. In some embodiments, as the recesses R1 extends into the substrate 110, back sides of the epitaxial structure 170S and 170D may be lower than a top surface of the substrate 110. The source/drain epitaxial structures 170S/170D may be formed by performing an epitaxial growth process that provides an epitaxial material on the fins FS. Suitable epitaxial processes include CVD deposition techniques (e.g., vapor-phase epitaxy (VPE) and/or ultra-high vacuum CVD (UHV-CVD)), molecular beam epitaxy, and/or other suitable processes. The epitaxial growth process may use gaseous and/or liquid precursors, which interact with the composition of semiconductor materials of the fins FS and the channel layers 124.

The source/drain epitaxial structures 170S/170D may be in-situ doped during the epitaxial process by introducing doping species including: p-type dopants, such as boron; n-type dopants, such as phosphorus or arsenic; and/or other suitable dopants including combinations thereof. If the source/drain epitaxial structures 170S/170D are not in-situ doped, an implantation process (i.e., a junction implant process) is performed to dope the source/drain epitaxial structures 170S/170D. In some exemplary embodiments, the source/drain epitaxial structures 170S/170D in an NFET device include SiP, SiC, SiPC, SiAs, Si, or combination thereof. The n-type doping concentration of the source/drain epitaxial structures 170S/170D (e.g., phosphorus, arsenic, or both) in the NFET device may be in a range from about 2E19/cm³ to about 3E21/cm³. In some exemplary embodiments, the source/drain epitaxial structures 170S/170D in a PFET device include SiGe doped with boron, or SiGeC doped with boron, Ge doped with boron, Si doped with boron, or combination. The p-type doping concentration of the source/drain epitaxial structures 170S/170D (e.g., boron) in the PFET device may be in a range from about 1E19/cm³ to about 6E20/cm³.

In the present embodiments, the source/drain epitaxial structures 170S/170D are in parallel with the direction Y where the dummy gate structures 140 extends along. The source/drain epitaxial growth from bottom to top may result in top wider shape. For example, each of the source/drain epitaxial structures 170S/170D may have a front-side surface and a back-side surface, and the front-side surface is wider than the back-side surface. Stated differently, the front-side surface of the source/drain epitaxial structures 170S/170D has a dimension D1 along the direction Y and the back-side surface of the source/drain epitaxial structures 170S/170D has a dimension D2 along the direction Y, and the dimension DI is greater than the dimension D2. In some embodiments, the dimension D1 is greater than 1.2 times the dimension D2. In some embodiments of the present disclosure, for the source/drain epitaxial structures 170S/170D of NFET and PFET, a ratio of the dimension D1 to the dimension D2 may be in a range from about 1.2 to about 2.5.

A dielectric material 180 is formed over the substrate 110 and filling the space between the dummy gate structures 140. In some embodiments, the dielectric material 180 includes a contact etch stop layer (CESL) and an interlayer dielectric (ILD) layer formed in sequence. In some examples, the CESL includes a silicon nitride layer, silicon oxide layer, a silicon oxynitride layer, and/or other suitable materials having a different etch selectivity than the ILD layer. The CESL may be formed by plasma-enhanced chemical vapor deposition (PECVD) process and/or other suitable deposition or oxidation processes. The ILD layer is then deposited over the CESL. In some embodiments, the ILD layer includes materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials having a different etch selectivity than the CESL. The ILD layer may be deposited by a PECVD process or other suitable deposition technique.

After depositing the dielectric material 180, a planarization process may be performed to remove excessive materials of the dielectric material 180. For example, a planarization process includes a chemical mechanical planarization (CMP) process which removes portions of the dielectric material 180 overlying the dummy gate structures 140 and planarizes a top surface of the integrated circuit structure. In some embodiments, the CMP process also removes the hard mask layer 146 in the dummy gate structures 140 (as shown in FIG. 4) and exposes the dummy gate electrode layer 144.

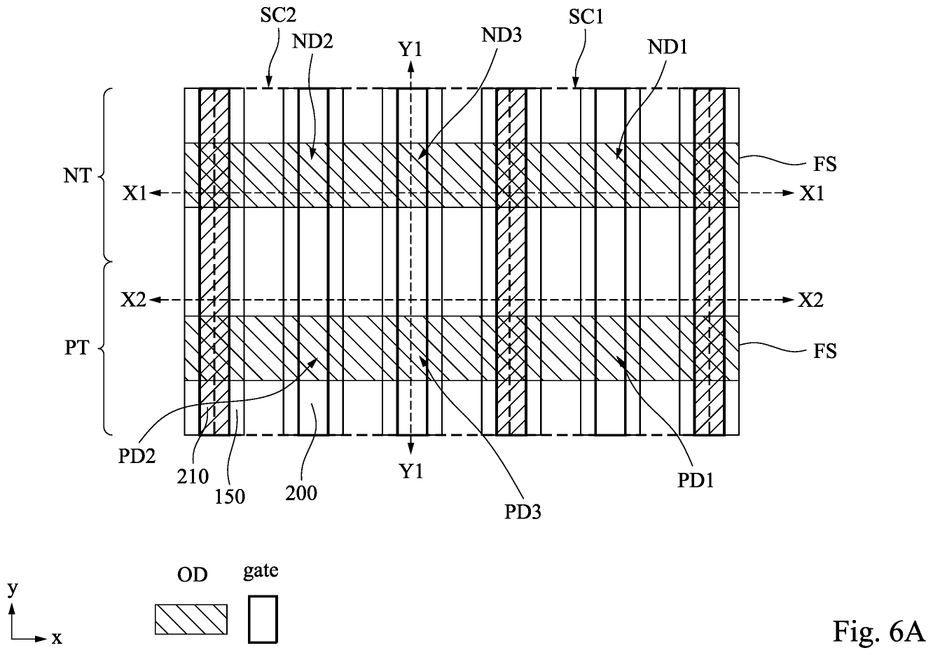

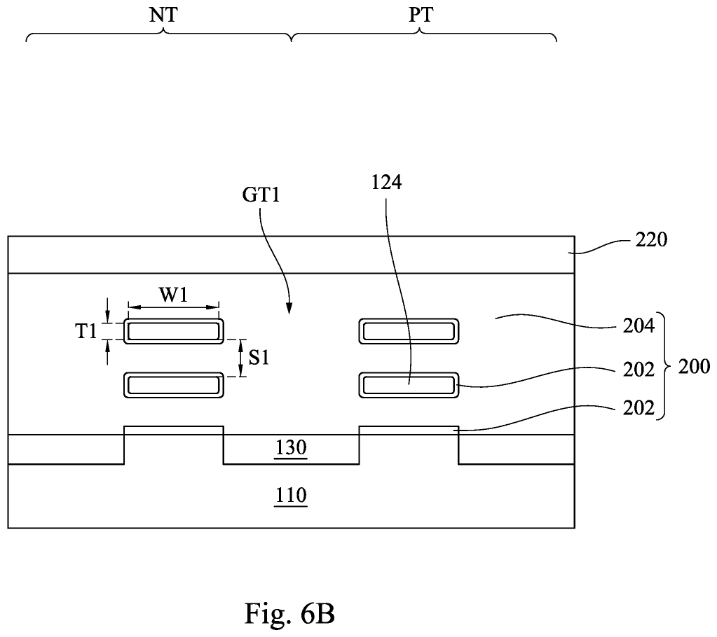

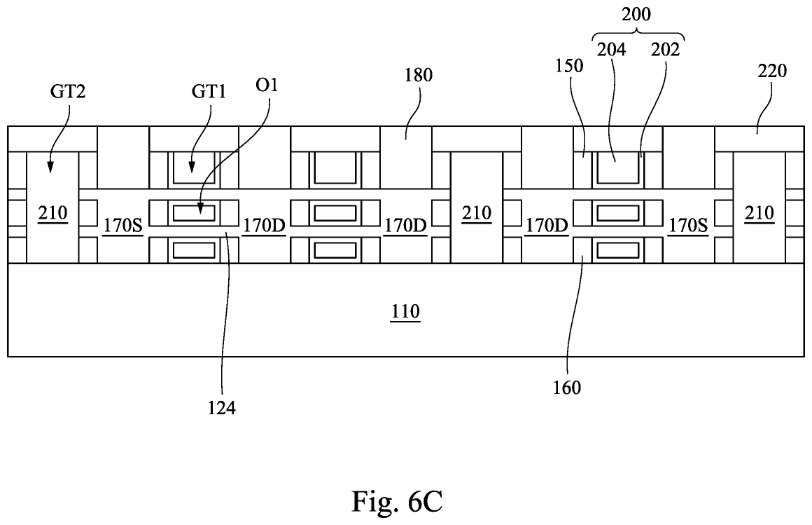

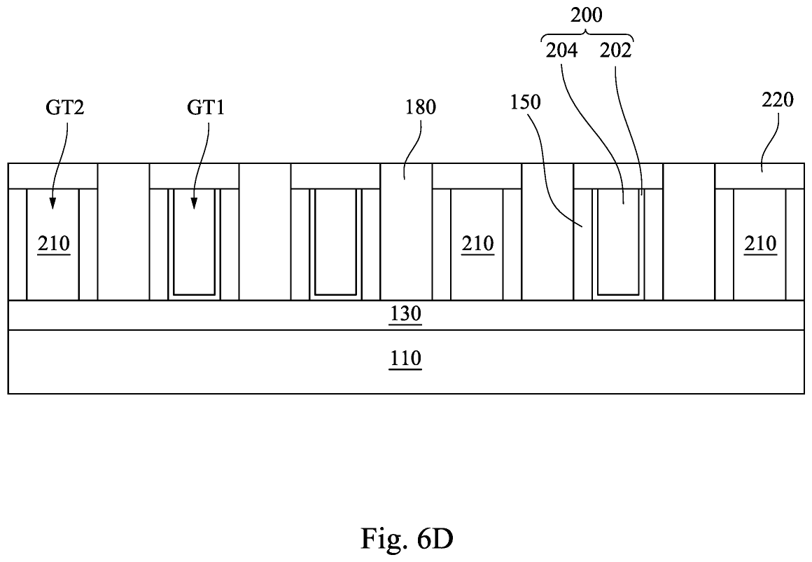

Reference is made to FIGS. 6A-6D. Some dummy gate structures 140 (referring to FIGS. 5A-5D) are replaced with metal gate structures 200. The metal gate replacement process may include removing a first group of the dummy gate structures 140 (referring to FIGS. 5A-5D), and removing the sacrificial layers 122 (referring to FIGS. 5B and 5C) therebelow. The removals form gate trenches GTI between the gate spacers 150 and openings/spaces O1 between neighboring channel layers 124. Replacement gate structures 200 are respectively formed in the gate trenches GTI and openings/spaces O1 to surround each of the channel layers 124 suspended in the gate trenches GTI.

In the illustrated embodiments, the dummy gate structures 140 (referring to FIGS. 5A-5D are removed by using a selective etching process (e.g., selective dry etching, selective wet etching, or a combination thereof) that etches the materials in dummy gate structures 140 (referring to FIGS. 5A-5D) at a faster etch rate than it etches other materials (e.g., gate spacers 150 and the dielectric material 180), thus resulting in gate trenches GT1 between corresponding gate spacers 150, with the top surface and sidewalls of the fins FS exposed in the gate trenches GT1. Subsequently, the sacrificial layers 122 in the gate trenches GTI are etched by using another selective etching process that etches the sacrificial layers 122 at a faster etch rate than it etches the channel layers 124, thus forming openings/spaces O1 between neighboring channel layers 124. In this way, the channel layers 124 become nanosheets suspended over the substrate 110 and between the source/drain epitaxial structures 170S/170D. This step is also called a channel release process. In some embodiments, the nanosheets 124 can be interchangeably referred to as nanowires, nanoslabs and nanorings, depending on their geometry. For example, in some other embodiments the channel layers 124 may be trimmed to have a substantial rounded shape (i.e., cylindrical) due to the selective etching process for completely removing the sacrificial layers 122. In that case, the resultant channel layers 124 can be called nanowires.

In some embodiments, the sacrificial layers 122 are removed by using a selective wet etching process. In some embodiments, the sacrificial layers 122 are SiGe and the channel layers 124 are silicon allowing for the selective removal of the sacrificial layers 122. In some embodiments, the selective wet etching includes an APM etch (e.g., ammonia hydroxide-hydrogen peroxide-water mixture). In some embodiments, the selective removal includes SiGe oxidation followed by a SiGeOₓ removal. For example, the oxidation may be provided by O₃ clean and then SiGeOₓ removed by an etchant such as NH₄OH that selectively etches SiGeO), at a faster etch rate than it etches Si. Moreover, because oxidation rate of Si is much lower (sometimes times lower) than oxidation rate of SiGe, the channel layers 124 may remain substantially intact during the channel release process. In some embodiments, both the channel release step and the previous step of laterally recessing sacrificial layers use a selective etching process that etches SiGe at a faster etch rate than etching Si, and therefore these two steps may use the same etchant chemistry in some embodiments. In this case, the etching time/duration of channel release step is longer than the etching time/duration of the previous step of laterally recessing sacrificial layers, so as to completely remove the sacrificial SiGe layers.

The gate structures 200 may be final gates of GAA FETs. The final gate structure may be a high-k/metal gate stack, however other compositions are possible. In some embodiments, each of the gate structures 200 forms the gate associated with the multi-channels provided by the plurality of nanosheets 124. For example, high-k/metal gate structures 200 are formed within the openings O1 provided by the release of nanosheets 124. In various embodiments, the high-k/metal gate structure 200 includes a gate dielectric layer 202 around the nanosheets 124 and a gate metal layer 204 formed around the gate dielectric layer 202 and filling a remainder of gate trenches GT1. Formation of the high-k/metal gate structures 200 may include one or more deposition processes to form various gate materials, followed by a CMP processes to remove excessive gate materials. Thus, n-type devices ND1-ND3 (e.g., NMOSFET) and p-type devices PD1-PD3 (e.g., PMOSFET), shown as GAA FETs, are formed.

In some embodiments, a channel width WI of the device (e.g., GAA FET), i.e., a width of the nanosheets 124, may be in a range from about 4 nanometers to about 70 nanometers. In some embodiments, a channel thickness T1 of the device (e.g., GAA FET), i.e., a thickness of the nanosheets 124, is in a range from about 4 nanometers to about 10 nanometers. In some embodiments, a channel space S1 of the device (e.g., GAA FET), i.e., a space between two adjacent nanosheets 124, is in a range from about 6 nanometers to about 20 nanometers. The channel region of said vertically stacked multiple channels (sheets) GAA transistors has vertically sheet pitch (i.e., a sum of the thickness T1 and the space S1) in a range from about 10 nanometers to about 30 nanometers.

In some embodiments, the gate dielectric layer 202 includes an interfacial layer formed around the nanosheets 124 and a high-k gate dielectric layer formed around the interfacial layer. The interfacial layer may be silicon oxide formed on exposed surfaces of semiconductor materials in the gate trenches GT1 by using, for example, thermal oxidation, chemical oxidation, wet oxidation or the like. As a result, surface portions of the nanosheets 124 and the substrate 110 exposed in the gate trenches GT1 are oxidized into silicon oxide to form interfacial layer. In some embodiments, the high-k gate dielectric layer includes dielectric materials such as hafnium oxide (HfO₂), hafnium silicon oxide (HfSiO), hafnium silicon oxynitride (HfSiON), hafnium tantalum oxide (HfTaO), hafnium titanium oxide (HMO), hafnium zirconium oxide (HfZrO), lanthanum oxide (LaO), zirconium oxide (ZrO), titanium oxide (TiO), tantalum oxide (Ta₂O₅), yttrium oxide (Y₂O₃), strontium titanium oxide (SrTiO₃, STO), barium titanium oxide (BaTiO₃, BTO), barium zirconium oxide (BaZrO), hafnium lanthanum oxide (HfLaO), lanthanum silicon oxide (LaSiO), aluminum silicon oxide (AlSiO), aluminum oxide (Al₂O₃), the like, or combinations thereof.

In some embodiments, the gate metal layer 204 includes one or more metal layers. For example, the gate metal layer 204 may include one or more work function metal layers stacked one over another and a fill metal filling up a remainder of gate trenches GT1. The one or more work function metal layers in the gate metal layer 204 provide a suitable work function for the high-k/metal gate structures 200. The work function metal layers may include TiN, TaN, TiAl, TiAlN, TaAl, TaAlN, TaAlC, TaCN, WNC, Co, Ni, Pt, W, or combination thereof. NMOSFET and PMOSFET may include the same work function material, or different work function materials. For example, n-type work function metals in the region NT for NMOSFET may exemplarily include, but are not limited to, titanium aluminide (TiAl), titanium aluminum nitride (TiAlN), carbo-nitride tantalum (TaCN), hafnium (Hf), zirconium (Zr), titanium (Ti), tantalum (Ta), aluminum (Al), metal carbides (e.g., hafnium carbide (HfC), zirconium carbide (ZrC), titanium carbide (TiC), aluminum carbide (AlC)), aluminides, and/or other suitable materials. P-type work function metal in the region PT for PMOSFET may exemplarily include, but are not limited to, titanium nitride (TiN), tungsten nitride (WN), tungsten (W), ruthenium (Ru), palladium (Pd), platinum (Pt), cobalt (Co), nickel (Ni), conductive metal oxides, and/or other suitable materials. In some embodiments, the fill metal in the gate metal layer 204 may exemplarily include, but are not limited to, tungsten, aluminum, copper, nickel, cobalt, titanium, tantalum, titanium nitride, tantalum nitride, nickel silicide, cobalt silicide, TaC, TaSiN, TaCN, TiAl, TiAlN, or other suitable materials. One for more lithography and patterning processes may be performed for forming the work-function metals for NMOSFET and forming the work-function metals for PMOSFET.

In some embodiments, before or after replacing the first group of the dummy gate structures 140 with the metal gate structures 200, a second group of dummy gate structures 140 is replaced with isolation features 210, which may also be referred to as dielectric gates. The dielectric gate replacement process may include removing the second group of the dummy gate structures 140 (referring to FIGS. 5A-5D), and removing the sacrificial layers 122 and channel layers 124 (referring to FIGS. 5B and 5C) therebelow. The removals form gate trenches GT2 between the gate spacers 150 and between the inner spacers 160. The isolation features 210 are respectively formed in the gate trenches GT2. In some embodiments, the isolation features 210 includes suitable dielectric materials, such as silicon oxide (SiO₂), a silicon nitride (SiN), a silicon carbide (SiC), a silicon oxynitride (SiON), other suitable materials, and/or combinations thereof. The dielectric material may be deposited by a PECVD process or other suitable deposition technique. After depositing the dielectric material, a planarization process may be performed to remove excessive materials of the dielectric material. For example, a planarization process includes a chemical mechanical planarization (CMP) process which removes portions of the dielectric material 180 overlying gate structures 140/200 and planarizes a top surface of the integrated circuit structure.

After the formation of the metal gate structures 200 and the isolation features (or dielectric gates) 210, top surfaces of the metal gate structures 200, the isolation features 210, and the gate spacers 150 may be recessed by suitable etching process. The dielectric material 180 may have a higher etch resistance to the etching process than that of the metal gate structures 200, the isolation features 210, and the gate spacers 150. Hard masks 220 may be formed over the recessed top surfaces of the metal gate structures 200, the isolation features 210, and the gate spacers 150. Formation of the hard masks 220 may include depositing suitable dielectric materials over the recessed top surfaces of the metal gate structures 200, the isolation features 210, and the gate spacers 150, followed by a CMP process. The dielectric material of the hard masks 220 may include silicon nitride, silicon carbide, silicon oxynitride, the like, or the combination thereof. Through the configurations, the metal gate structures 200 and the isolation features are capped and protected by the hard masks 220.

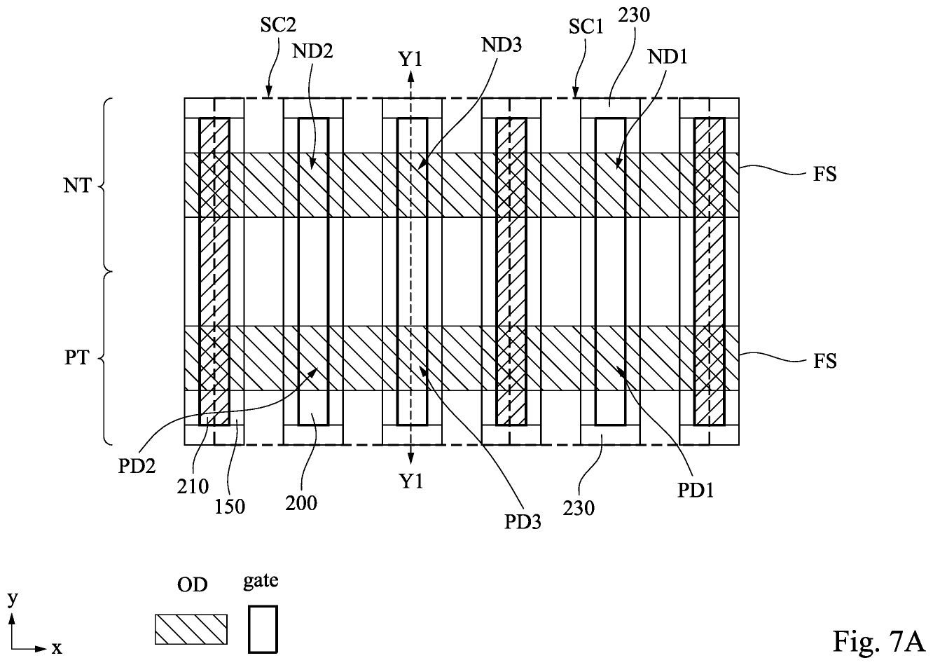

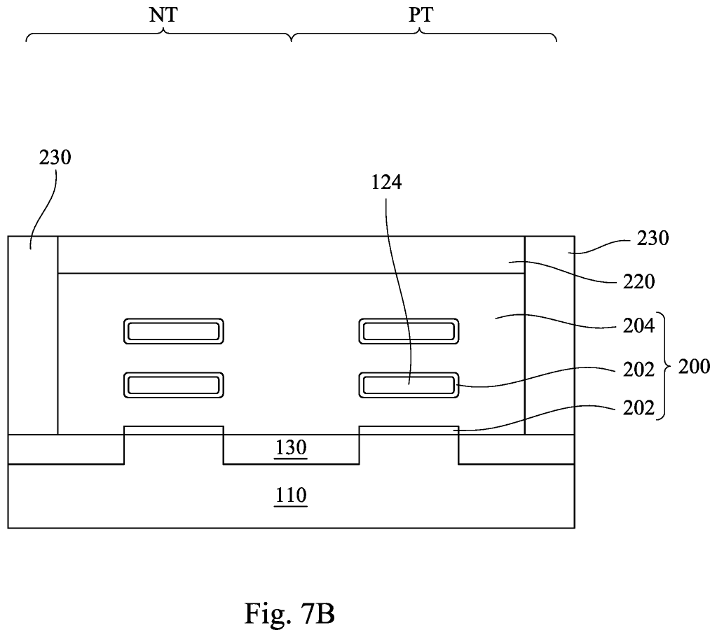

Reference is made to FIGS. 7A and 7B. A gate end dielectric 230 may either be disposed between gate structures 200, at an end of a gate structure 200 after a gate cut process, between isolation features (or dielectric gates) 210, at an end of an isolation feature (or dielectric gate) 210 after a gate cut process. In some embodiments, the gate end dielectric 230 may be referred to as dielectric plugs. The gate end dielectric layer 230 may include suitable dielectric materials, such as oxide, Si₃N₄, other nitride-base dielectric, carbon-base dielectric, high k material (e.g., having a k value equal to or greater than 9), or other suitable dielectric material. Formation of the gate end dielectric 230 may include etching away portions of the metal gate structures 200, the isolation features (or the dielectric gates) 210, and the hard masks 220 to expose underlying dielectric materials (e.g., the isolation features 130), and depositing the suitable gate end dielectric materials over the underlying dielectric materials (e.g., the isolation features 130). A CMP process may be performed to remove excess portions of the gate end dielectric materials, leaving the remaining portions forming the gate end dielectric 230.

Through the configuration, the gate end dielectric 230 and the isolation features (or the dielectric gates) 210 are located at boundaries of the cells SC1 and SC2 for isolation purposes. For example, one of the isolation features (or the dielectric gates) 210 is interposing the cells SC1 and SC2 in the layout. In some embodiments, a gate length of the gate structure 200 between two gate end dielectrics 230 may be in a range from about 6 nanometers to about 20 nanometers.

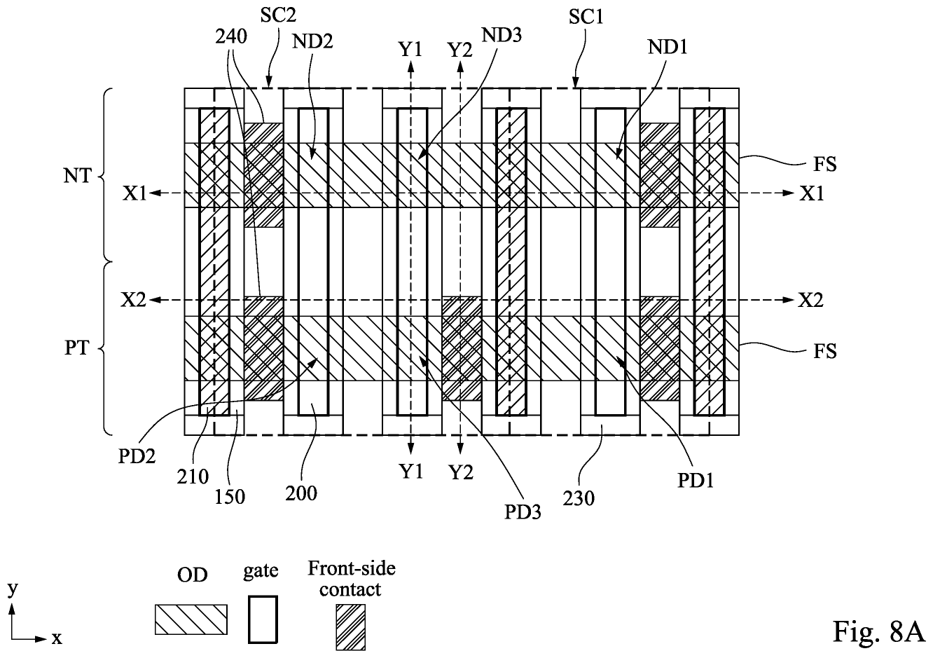

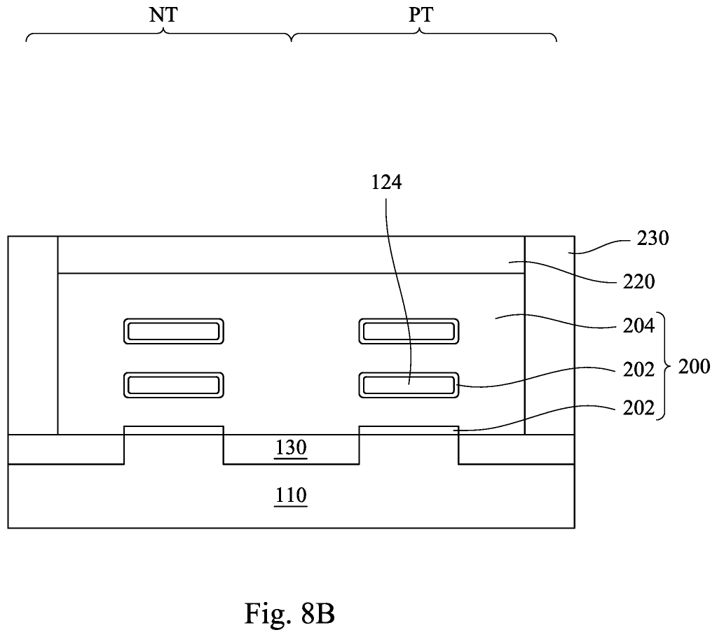

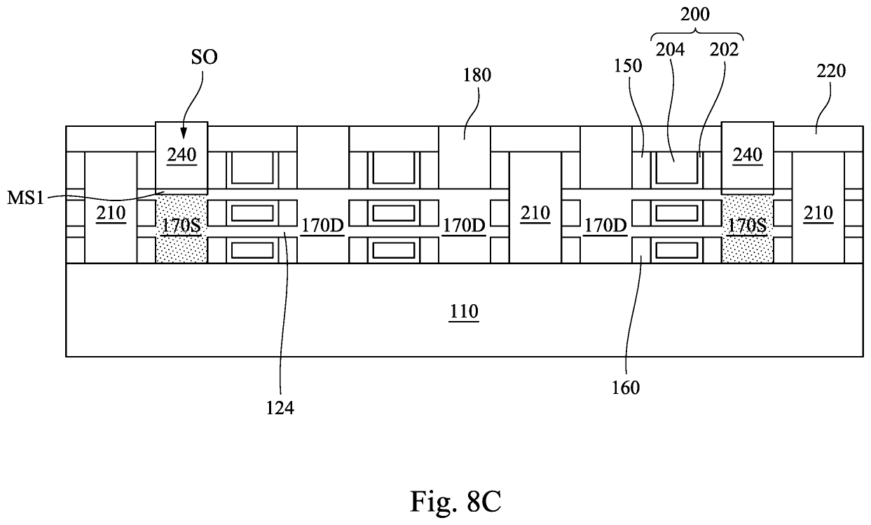

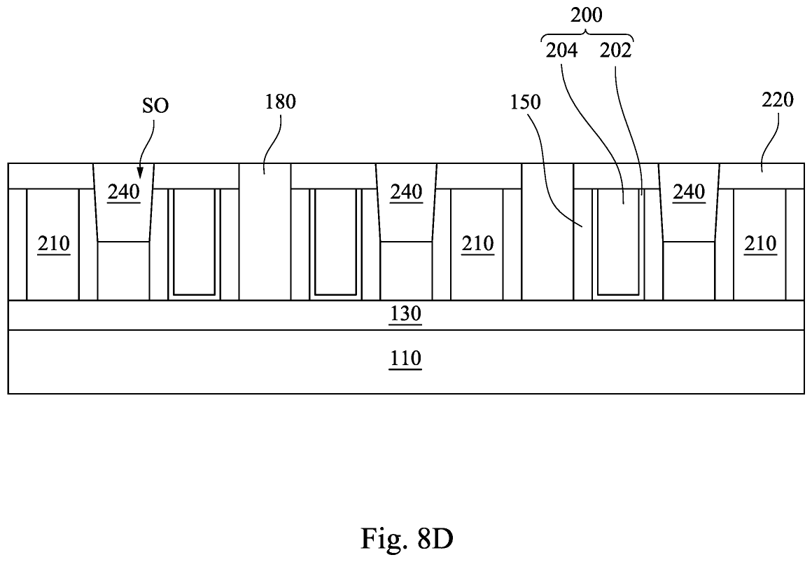

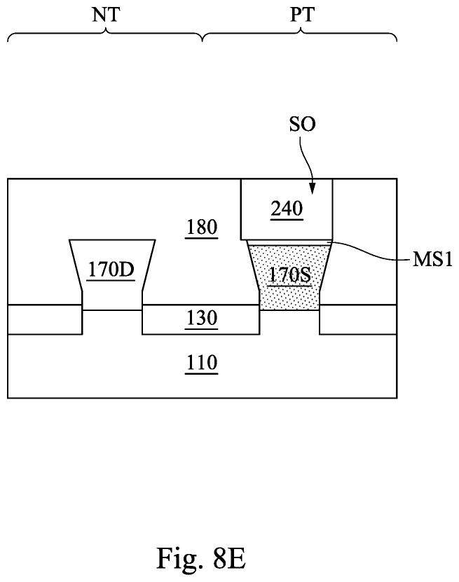

Reference is made to FIGS. 8A-8E. Source contacts 240 are formed over the source epitaxial structures 170S. In some embodiments, the formation of the source contacts 240 includes etching source contact openings SO through the dielectric material 180 to expose top surfaces of the source epitaxial structures 170S, and depositing one or more metal materials into the source contact openings SO. The metal materials may include W, Ru, Co, Cu, Ti, TiN, Ta, TaN, Mo, Ni, Pt, Ir, Rh, the like or combinations thereof. The metal materials are deposited to fill the source contact openings SO by using suitable deposition techniques (e.g., CVD, PVD, ALD, the like or combinations thereof). Subsequently, a CMP process can be performed to remove excess metal materials outside the source contact openings SO, while leaving metal materials in the source contact openings SO to serve as the source contacts 240. The source contacts 240 may include a single metal material or multiple metal material layers. As the front-side surface of source epitaxial structures 170S is wider than the back-side surface of source epitaxial structures 170S, the front-side surface of source epitaxial structures 170S may provide a large area for contact landing, thereby reducing the contact resistance.

The source contacts 240 may be isolated from the gate structure 200 by the gate spacers 150. The source contacts 240 may be laterally overlapped with the gate structure 200. In some embodiments, a vertical distance HI between a bottom surface of the source contact 240 and a top surface of the gate structure 200 (i.e., a vertically overlapping region of the source contact 240 and the gate structure 200) may be in a range from about 5 nanometers to about 25 nanometers. If the vertical distance H1 is less than about 5 nanometers, the formation of the work function metals of the gate structure H1 may become difficult. If the vertical distance HI is greater than about 25 nanometers, the height of the front-side source contact may increase, resulting higher electrical resistance.

In some embodiments, prior to depositing the metal materials, metal silicide regions MS1 may be formed on exposed top surfaces of the source epitaxial structures 170S by using a silicidation process. Silicidation may be formed by blanket depositing a metal layer over the exposed source epitaxial structures 170S, annealing the metal layer such that the metal layer reacts with silicon (and germanium if present) in the source epitaxial structures 1705 to form the metal silicide regions MSI, and thereafter removing the non-reacted metal layer. In some embodiments, the metal layer used in the silicidation process includes nickel, cobalt, titanium, tantalum, platinum, tungsten, other noble metals, other refractory metals, rare earth metals or their alloys. Thus, metal silicide regions MSI may be between the source contacts 240 and the source epitaxial structure 170S.

In some embodiments, prior to forming the metal silicide regions MS1, one or more extra implantation processes may be performed for increasing a dopant concentration of the source epitaxial structure 170S, thereby lowering the source contact resistance as well as source region resistance. The extra implantation processes may include an n-type implantation using n-type dopants (e.g., phosphorus (P31), arsenic, Ge, or the combination thereof) for NMOSFET, and/or an p-type implantation using n-type dopants (e.g., boron (B11), BF₂, Ge, or the combination thereof) for PMSOFET. One or more implantation masks may be used during the implantation processes. For example, when the n-type implantation is performed to the region NT for NMOSFET, implantation masks are used to cover the region PT for PMSOFET. For example, when the p-type implantation is performed to the region PT for PMOSFET, implantation masks are used to cover the region NT for NMSOFET. The extra implantation processes may further include Ge implantation process. Through the configuration, in the region NT for NMOSFET, the n-type dopant concentration of the source epitaxial structure 170S is higher than the n-type dopant concentration of the drain epitaxial structure 170D. Similarly, in the region PT for PMSOFET, the p-type dopant concentration of the source epitaxial structure 170S is higher than the p-type dopant concentration of the drain epitaxial structure 170D. After the extra implantations, the metal silicide regions MS1 and the source contacts 240 can be formed. As shown in the figures, the source epitaxial structures 170S are filled with dotted pattern for indicating their higher dopant concentration than that of the drain epitaxial structures 170D.

FIGS. 9A-9F illustrate formation of a front-side multilayer interconnection (MLI) structure FMI over the substrate 110. The front-side MLI structure FMI may include at least three front-side metallization layers. The number of front-side metallization layers may vary according to design specifications of the integrated circuit structure. Only two front-side metallization layers (e.g., the metallization layers 270 and 280) are illustrated in FIGS. 9A-9F for the sake of simplicity. The metallization layer 270 is the metallization layer closest to the devices ND1-ND3 and PD1-PD3. The metallization layer 270 may also be referred to as the lowest metallization layer of the front-side MLI structure FMI. The front-side metallization layers each comprise one or more front-side inter-metal dielectric (IMD) layers, one or more horizontal interconnects respectively extending horizontally in the IMD layers, and one or more vertical interconnects respectively extending vertically in the IMD layers. For example, the front-side metallization layer 270 comprises IMD layers 271 and 273, horizontal interconnects (e.g., metal lines 274) and vertical interconnects (e.g., metal via 272). The metal lines 274 of the lowest metallization layer 270 of the front-side MLI structure FMI may include a high power rail 274Vdd and a lower power rail 274Vss. The metal via 272 is in contact with the source contact 240 to make power electrical connection from the metal lines 274 (e.g., the high power rail 274Vdd and/or the lower power rail 274Vss) to the source epitaxial structure 170S. In some embodiments, from the layout top view as shown in FIG. 9A, the metal via 272 may be a rectangular or an ellipse shape via, and the dimension ratio of a longer side of the metal via 212 to a short side of the metal via 272 may be in a range from about 1.2 to about 5. The front-side metallization layer 280 may comprise the IMD layer 281, horizontal interconnects (e.g., metal lines 284) and vertical interconnects (e.g., metal via 282). The metal via 282 connects the metal lines 284 to the metal lines 274. In some embodiments, a routing direction of the metal lines 274 is different from or perpendicular to a routing direction of the metal lines 284. For example, the metal lines 274 extends along the direction X, and the metal line 284 extends along the direction Y.

The metallization layers 270 and 280 can be formed using, for example, a single damascene process, a dual damascene process, the like, or combinations thereof. In some embodiments, the IMD layers 271, 273, and 281 may include low-k dielectric materials having k values, for example, lower than about 4.0 or even 2.0 disposed between such conductive features. In some embodiments, the IMD layers 271, 273, and 281 may be made of, for example, phosphosilicate glass (PSG), borophosphosilicate glass (BPSG), fluorosilicate glass (FSG), SiOₓC_{y}, Spin-On-Glass, Spin-On-Polymers, silicon oxide, silicon oxynitride, combinations thereof, or the like, formed by any suitable method, such as spin-on coating, chemical vapor deposition (CVD), plasma-enhanced CVD (PECVD), or the like. The front-side metal lines and vias 272, 274, 282, and 284 may comprise metal materials such as W, Ru, Co, Cu, Ti, TiN, Ta, TaN, Mo, Ni, combinations thereof, or the like. In some embodiments, the front-side metal lines and vias 272, 274, 282, and 284 may further comprise one or more barrier/adhesion layers (not shown) to protect the respective front-side IMD layers 271, 273, and 281 from metal diffusion (e.g., copper diffusion) and metallic poisoning. The one or more barrier/adhesion layers may comprise titanium, titanium nitride, tantalum, tantalum nitride, or the like, and may be formed using physical vapor deposition (PVD), CVD, ALD, or the like.

FIGS. 10A-10F illustrate formation of back-side drain contacts 320 over back sides of drain epitaxial structures 170D. One or more processes are performed to remove materials at the back sides of source/drain epitaxial structures 170S/170D, thereby exposing the back sides of source/drain epitaxial structures 170S/170D. For example, a planarization process (e.g., a CMP process, or a grinding process) is performed to thinning down the substrate 110. The planarization process may also remove portions of or all the isolation structures 130. In some embodiments, after the planarization process, one or more etching process may be performed to remove the substrate 130 and the isolation structures 13. In some alternative embodiments, portions of the isolation structures 130 may remain at back sides of the devices.

A back-side dielectric layer 310 is deposited over the back sides of the devices, e.g., the back sides of the source/drain epitaxial structures 170S/170D and the back sides of the high-k/metal gate structures 200. In some embodiments, the back-side dielectric layer 310 may include, for example, a low-k dielectric material (with dielectric constant lower than about 7) such as SiO₂, SiN, SiCN, SiOC, SiOCN, the like, or combinations thereof. In some embodiments, the back-side dielectric layer 310 includes a high-k dielectric material such as HfO₂, ZrO₂, HfAlOₓ, HfSiOₓ and Al₂O₃, the like or combinations thereof. A CMP process is may be performed on the back-side dielectric layer 310.

Drain contacts 320 are formed over the back sides of the drain epitaxial structures 170D. In some embodiments, the formation of the drain contacts 320 includes etching drain contact openings DO through the back-side dielectric layer 310 to expose back sides of the drain epitaxial structures 170D, and depositing one or more metal materials into the drain contact openings DO. The metal materials may include W, Ru, Co, Cu, Ti, TiN, Ta, TaN, Mo, Ni, the like or combinations thereof. The metal materials are deposited to fill the drain contact openings DO by using suitable deposition techniques (e.g., CVD, PVD, ALD, the like or combinations thereof). Subsequently, a CMP process can be performed to remove excess metal materials outside the drain contact openings DO, while leaving metal materials in the drain contact openings DO to serve as the drain contacts 320.

In some embodiments where the back sides of the drain epitaxial structures 170D is lower than a top surface of the substrate 110 (referring to FIGS. 9B, 9E, and 9F), the formed drain contacts 320 may not laterally overlap the gate structure 200. Stated differently, a top surface of the drain contacts 320 may be lower than a bottom surface of the gate structure 200. In some alternative embodiments, depending on source/drain region recessing (e.g., the etching of the recesses R1 in FIG. 4) and the etching of the drain contact openings DO, a top surface of the drain contact 320 may be equal to or higher than a bottom surface of the gate structure 200, and the drain contacts 320 may laterally overlap the gate structure 200. For example, a vertical distance between the top surface of the drain contact 320 and the bottom surface of the gate structure 200 (i.e., a vertically overlapping region of the drain contact 320 and the gate structure 200) may be in a range from about 0 nanometer to about 3 nanometers. As the vertical distance between the top surface of the drain contact and the bottom surface of the gate structure is less than the vertical distance H1 (e.g., from about 5 nanometers to about 25 nanometers), or the drain contacts 320 does not laterally overlap the gate structure 200, the back-side drain node connection is more advantages for capacitance reduction.

In some embodiments, prior to depositing the metal materials, metal silicide regions may be formed on exposed back sides of the drain epitaxial structures 170D by using a silicidation process. Silicidation may be formed by blanket depositing a metal layer over the exposed drain epitaxial structures 170D, annealing the metal layer such that the metal layer reacts with silicon (and germanium if present) in the drain epitaxial structures 170D to form the metal silicide regions, and thereafter removing the non-reacted metal layer. In some embodiments, the metal layer used in the silicidation process includes nickel, cobalt, titanium, tantalum, platinum, tungsten, other noble metals, other refractory metals, rare earth metals or their alloys. Thus, metal silicide regions may be between the drain contacts 320 and the drain epitaxial structures 170D.

FIG. 11 illustrate formation of gate contact via GC over back sides of the gate structure 200. In some embodiments, the formation of the gate contact via GC includes depositing a dielectric layer 331 over the back-side dielectric layer 310, etching an opening through the back-side dielectric layer 310 and the dielectric layer 331 to expose back sides of the gate structure 200, and depositing one or more metal materials into the opening. The metal materials may include Ti, TiN, TaN, Co, Ru, Pt, W, Al, Cu, the like or combinations thereof. The metal materials are deposited to fill the opening by using suitable deposition techniques (e.g., CVD, PVD, ALD, the like or combinations thereof). Subsequently, a CMP process can be performed to remove excess metal materials outside the opening, while leaving metal materials in the opening to serve as the gate contact via GC.

FIGS. 12A-12F illustrate formation of a back-side multilayer interconnection (MLI) structure BMI over the substrate 110. The back-side MLI structure BMI may include at least three back-side metallization layers. The number of back-side metallization layers may vary according to design specifications of the integrated circuit structure. Only two back-side metallization layers (e.g., the metallization layers 330 and 340) are illustrated in FIGS. 12A-12F for the sake of simplicity. The back-side metallization layers each comprise one or more back-side inter-metal dielectric (IMD) layers, one or more horizontal interconnects respectively extending horizontally in the IMD layers, and one or more vertical interconnects respectively extending vertically in the IMD layers. For example, the back-side metallization layer 330 comprises IMD layers 331 and 333, horizontal interconnects (e.g., metal lines 334) and vertical interconnects (e.g., metal via 332). The metal lines 334 may include signal conductors. The metal via 332 is in contact with the drain contact 320 to make signal electrical connection to the drain epitaxial structure 170D. For example, the back-side metallization layer 340 comprises the IMD layer 341, horizontal interconnects (e.g., metal lines 344), and vertical interconnects (e.g., metal via 342). The metal via 342 may connect the metal lines 344 to the metal lines 334. In some embodiments, a routing direction of the metal lines 334 is different from or perpendicular to a routing direction of the metal lines 344. For example, the metal lines 334 extends along the direction X, and the metal line 344 extends along the direction Y.

The metallization layers 330 and 340 can be formed using, for example, a single damascene process, a dual damascene process, the like, or combinations thereof. In some embodiments, the IMD layers 331, 333, and 341 may include low-k dielectric materials having k values, for example, lower than about 4.0 or even 2.0 disposed between such conductive features. In some embodiments, the IMD layers 331, 333, and 341 may be made of, for example, phosphosilicate glass (PSG), borophosphosilicate glass (BPSG), fluorosilicate glass (FSG), SiOₓ,C_{y}, Spin-On-Glass, Spin-On-Polymers, silicon oxide, silicon oxynitride, combinations thereof, or the like, formed by any suitable method, such as spin-on coating, chemical vapor deposition (CVD), plasma-enhanced CVD (PECVD), or the like. The back-side metal lines and vias 332, 334, 342, and 344 may comprise metal materials such as W, Ru, Co, Cu, Ti, TiN, Ta, TaN, Mo, Ni, combinations thereof, or the like. In some embodiments, the back-side metal lines and vias 332, 334, 342, and 344 may further comprise one or more barrier/adhesion layers (not shown) to protect the respective back-side IMD layers 331, 333, and 341 from metal diffusion (e.g., copper diffusion) and metallic poisoning. The one or more barrier/adhesion layers may comprise titanium, titanium nitride, tantalum, tantalum nitride, or the like, and may be formed using physical vapor deposition (PVD), CVD, ALD, or the like.

As shown in the front-side layouts of FIG. 9A and the back-side layout of FIG. 12A, the standard cell SCI is formed as an inverter. For example, the n-type device ND1 and the p-type device PD1 share a continuous gate structure 200, source nodes of the n-type device NDI and the p-type device PD1 are respectively electrically connected to the front-side power rail 274Vss and 274Vdd, and drain nodes of the n-type device ND1 and the p-type device PD1 are respectively electrically connected to each other by sharing the same back-side drain contact 320. An input terminal of the standard cell SC1 may be connected to the back-side interconnection structure BMI. For example, the gate structure 200 of the n-type device ND1 and the p-type device PD1 may be electrically connected to one of the back-side metal lines 334 by one of the gate contact vias GC. An output terminal of the standard cell SC1 may be connected to the back-side interconnection structure BMI. For example, the drain nodes of the n-type device ND1 and the p-type device PD1 may be electrically connected to another one of the back-side metal lines 334 by the back-side drain contact 320.

As shown in the front-side layouts of FIG. 9A and the back-side layout of FIG. 12A, the standard cell SC2 is formed as a NAND. For example, the n-type device ND2 and the p-type device PD2 share a continuous gate structure 200, the n-type device ND3 and the p-type device PD3 share a continuous gate structure 200, source nodes of the p-type device PD2 and PD3 are electrically connected to the front-side power rail Vdd (e.g., the metal line 274Vdd), a source node of the n-type device ND1 is electrically connected to the front-side power rail Vss (e.g., the metal line 274Vss), drain nodes of the p-type device PD2 and PD3 share the same drain epitaxial structure, and a drain node of the n-type device ND2 and a source node of the n-type device ND3 share the same epitaxial structure, the drain nodes of the p-type device PD2 and PD3 are electrically connected to a drain node of the n-type device ND3. Two input terminals of the standard cell SC2 may be connected to the back-side interconnection structure BMI. For example, the gate structure 200 of the device PD2 and ND2 may be connected to one of the back-side metal lines 334 by one of the gate contact vias GC. And, the gate structure 200 of the device PD3 and ND3 may be connected to another one of the back-side metal lines 334 by another one of the gate contact vias GC. An output terminal of the standard cell SC2 may be connected to the back-side interconnection structure BMI. For example, the drain nodes of the p-type device PD2 and PD3 and a drain node of the n-type device ND3 may be connected to still another one of the back-side metal lines 334 by the back-side drain contacts 320.

In above fabrication process, the formation of the front-side interconnect structure FMI is followed by the formation of the back-side interconnect structure BMI. In the embodiments, prior to the formation of the back-side interconnect structure BMI, a protection layer PL may be optionally formed over a top surface of the front-side interconnect structure FMI. The protection layer PL may include one or more suitable layers, such as dielectric layer, a polysilicon layer, or combination thereof. During the formation of the back-side interconnect structure BMI, the protection layer PL may protect the top surface of the front-side interconnect structure FMI. After the formation of the back-side interconnect structure BMI, the protection layer PL may be removed.

In some alternative embodiments, the formation of the back-side interconnect structure BMI is followed by the formation of the front-side interconnect structure FMI. In the embodiments, prior to the formation of the front-side interconnect structure FMI, a protection layer may be optionally formed over a top surface of the back-side interconnect structure BMI (or a back-side surface of the back-side interconnect structure BMI). The protection layer may include one or more suitable layers, such as dielectric layer, a polysilicon layer, or combination thereof. During the formation of the front-side interconnect structure FMI, the protection layer may protect the top surface of the back-side interconnect structure BMI (or a back-side surface of the back-side interconnect structure BMI). After the formation of the e front-side interconnect structure FMI, the protection layer PL may be removed.

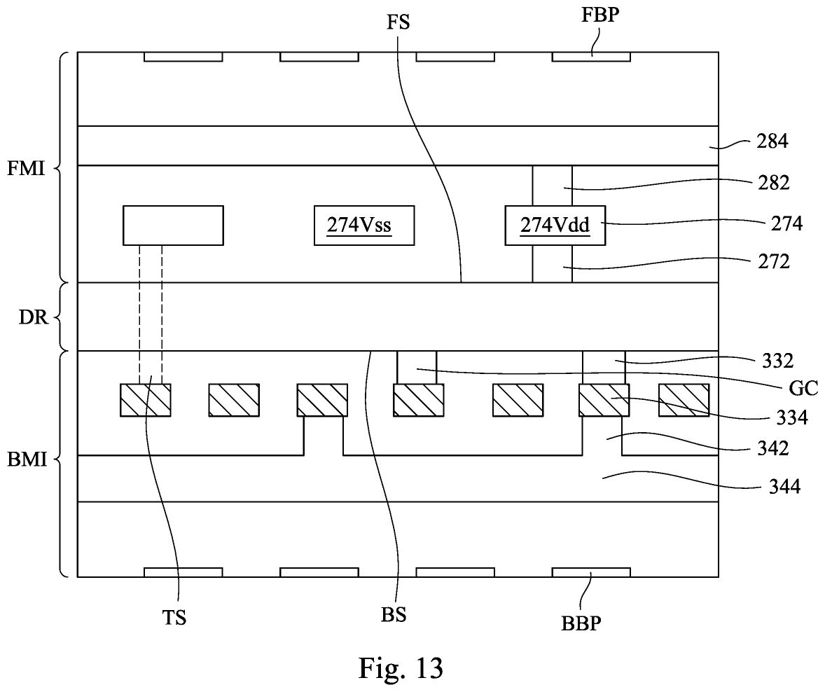

FIG. 13 is a cross-sectional views of an integrated circuit chip according to some embodiments of the present disclosure. The devices ND1-ND3 and PD1-PD3 in FIGS. 9A and 12A are illustrated as the device layer DR in FIG. 13. The front-side interconnect structure FMI and the back-side interconnect structure BMI are respectively at a front side FS of the device layer DR and at a back side BS of the device layer DR. In some embodiments of the present disclosure, for the integrated circuit structure, lowest-level power conductors (e.g., the power rails 274Vdd and 274Vss) are located on the front side FS of the device layer DR, and signal conductors are located on the back side BS of the device layer DR. Source node of the device layer DR may be connected to front-side contact 240 and the power rails 274Vdd/274Vss for contact resistance reduction, thereby reducing the IR drop in power transmission. Drain node of the device layer DR may be connected to back-side contact 330 and signal metal lines 334 for capacitance reduction, thereby reducing the RC delay in signal transmission.

In some embodiments, a structure fabricated through the fabrication process shown in FIGS. 1-12F is dividing into plural separated integrated circuit chips. Each integrated circuit chip may include plural front-side bump pads FBP over and electrically connected to the front-side interconnect structure FMI and plural back-side bump pads BBP over and electrically connected to the back-side interconnect structure BMI. Thus, by using suitable connecters (e.g., bumps), the devices (e.g., the devices ND1-ND3 and PD1-PD3 in FIGS. 9A and 12A) of the device region DR can be electrically connected to other chip/substrate/wafer through the front-side bump pads FBP and the back-side bump pads BBP. In some embodiments, prior to the chip cutting process, one or more tap structures TS may be formed and extending from the front-side metallization layer (e.g., the power rails 274Vss and 274Vdd) to the back-side metallization layer (e.g., the metal lines 334), thereby establish back side to front side connection. The tap structures TS may include plural conductive features, one stacking over another, in which the conductive features of the tap structures TS may be formed along with the formation process of the front-side contact, front-side via, back-side contacts, and back-side via.

Based on the above discussions, it can be seen that the present disclosure offers advantages. It is understood, however, that other embodiments may offer additional advantages, and not all advantages are necessarily disclosed herein, and that no particular advantage is required for all embodiments. One advantage is that part of metal layers are moved to wafer back-side to reduce the routing loading as well as circuit density further improvement. The less metal tracks in same area/layer also benefits the metal conductor RC performance (e.g., lower resistance (e.g., wider width) or lower capacitance (e.g., larger space), or both). Another advantage is that the device structure adopts frond-side source node connection and back-side drain node connection. As the source/drain epitaxial growth from bottom to top results in top wider shape, the source node contact landed on top wider region to have contact resistance (Rc) reduction for addressing IR drop, and drain node landed on narrow bottom region to addressing RC delay. Still another advantage is that drain node connection moved to the back side also have extra capacitance reduction benefit between contact and gate. Still another advantage is that an extra doping species is added to lower down the front-side source contact resistance as well as source region resistance. Yet another advantage is that a process/structure co-optimization to achieve both high density and high speed applications.

In some embodiments of the present disclosure, an integrated circuit (IC) structure includes a transistor, a front-side interconnection structure, a back-side interconnection structure, a source contact, and a drain contact. The transistor includes a gate structure, a source epitaxial structure, and a drain epitaxial structure. The front-side interconnection structure includes a power rail. Each of the source and drain epitaxial structures has a front-side surface facing the front-side interconnection structure and a back-side surface facing the back-side interconnection structure, and the front-side surface is wider than the back-side surface. The source contact electrically connects the source epitaxial structure to the power rail of the front-side interconnection structure. The drain contact electrically connects the drain epitaxial structure to a first metal line of the back-side interconnection structure.

In some embodiments of the present disclosure, an integrated circuit (IC) structure includes a first transistor, a front-side interconnection structure, a first source contact, and a first front-side via. The first transistor includes a first gate structure and a first source epitaxial structure. The front-side interconnection structure includes a first power rail, wherein the first source epitaxial structure has a front-side surface facing the front-side interconnection structure and a back-side surface facing away from the front-side interconnection structure, and the front-side surface is wider than the back-side surface. The first source contact is over the front-side surface of the first source epitaxial structure. The first front-side via has a top surface in contact with the first power rail and a bottom surface in contact with the first source contact.

In some embodiments of the present disclosure, a method includes forming a transistor over a substrate, wherein the transistor comprises a gate structure, a source epitaxial structure, and a drain epitaxial structure; forming a source contact at a front-side surface of the source epitaxial structure; forming a front-side interconnection structure over the source contact; removing the substrate to expose a back-side surface of the drain epitaxial structure; forming a drain contact at the back-side surface of the drain epitaxial structure; and forming a back-side interconnection structure over the drain contact.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit (IC) structure, comprising:
a transistor comprising a gate structure, a source epitaxial structure, and a drain epitaxial structure;
a front-side interconnection structure, wherein the front-side interconnection structure comprises a power rail;
a back-side interconnection structure, wherein each of the source and drain epitaxial structures has a front-side surface facing the front-side interconnection structure and a back-side surface facing the back-side interconnection structure, and the front-side surface is wider than the back-side surface;
a source contact electrically connecting the source epitaxial structure to the power rail of the front-side interconnection structure; and
a drain contact electrically connecting the drain epitaxial structure to a first metal line of the back-side interconnection structure.

2. The IC structure of claim 1, further comprising a front-side via having a top surface in contact with the power rail and a bottom surface in contact with the source contact.

3. The IC structure of claim 1, wherein a first vertical distance between a top surface of the drain contact and a bottom surface of the gate structure is less than a second vertical distance between a bottom surface of the source contact and a top surface of the gate structure.

4. The IC structure of claim 1, wherein a top surface of the drain contact is lower than a bottom surface of the gate structure.

5. The IC structure of claim 1, wherein a top surface of the drain contact is level with or higher than a bottom surface of the gate structure, and a vertical distance between a top surface of the drain contact and a bottom surface of the gate structure is in a range from about 0 nanometer to about 3 nanometers.

6. The IC structure of claim 1, wherein a vertical distance between a bottom surface of the source contact and a top surface of the gate structure is in a range from about 5 nanometers to about 25 nanometers.

7. The IC structure of claim 1, further comprising:
a gate contact via electrically connecting the gate structure to a second metal line of the back-side interconnection structure.

8. The IC structure of claim 1, wherein a dopant concentration of the source epitaxial structure is higher than a dopant concentration of the drain epitaxial structure.

9. The IC structure of claim 1, further comprising:
a source silicide region on the front-side surface of the source epitaxial structure and in contact with the source contact; and
a drain silicide region on the back-side surface of the drain epitaxial structure and in contact with the drain contact.

10. The IC structure of claim 1, wherein the drain contact is wider than the back-side surface of the drain epitaxial structure.

11. An integrated circuit (IC) structure, comprising:
a first transistor comprising a first semiconductor layer, a first gate structure around the first semiconductor layer, and a first source epitaxial structure at a side of the first semiconductor layer;
a front-side interconnection structure comprising a first power rail, wherein the first source epitaxial structure has a front-side surface facing the front-side interconnection structure and a back-side surface facing away from the front-side interconnection structure, and the front-side surface is wider than the back-side surface;
a first source contact over the front-side surface of the first source epitaxial structure; and
a first front-side via having a top surface in contact with the first power rail and a bottom surface in contact with the first source contact.

12. The IC structure of claim 11, wherein the front-side interconnection structure comprises no metallization layer between the first power rail and the first source contact.

13. The IC structure of claim 11, further comprising:
a second transistor comprising a second semiconductor layer, a second gate structure around the second semiconductor layer, and a second source epitaxial structure at a side of the second semiconductor layer, wherein the second source epitaxial structure has a front-side surface facing the front-side interconnection structure and a back-side surface facing away from the front-side interconnection structure, and the front-side interconnection structure further comprises a second power rail at a voltage level different from that of the first power rail;
a second source contact over the front-side surface of the second source epitaxial structure; and
a second front-side via having a top surface in contact with the second power rail and a bottom surface in contact with the second source contact.

14. The IC structure of claim 13, wherein the first and second power rails are of a same metallization layer.

15. The IC structure of claim 11, further comprising:
a source silicide region on the front-side surface of the first source epitaxial structure and in contact with the first source contact, wherein the first transistor comprises a drain epitaxial structure, and a front-side surface of the drain epitaxial structure is free of a silicide region.

16. The IC structure of claim 11, wherein the first transistor further comprises a gate spacer between the first source contact and the first gate structure and an inner spacer between the first semiconductor layer and the first gate structure, and a k value of the inner spacer is greater than a k value of the gate spacer.

17. A method, comprising:
forming a transistor over a substrate, wherein the transistor comprises a gate structure, a source epitaxial structure, and a drain epitaxial structure;
forming a source contact at a front-side surface of the source epitaxial structure;
forming a front-side interconnection structure over the source contact;
removing the substrate to expose a back-side surface of the drain epitaxial structure;
forming a drain contact at the back-side surface of the drain epitaxial structure; and
forming a back-side interconnection structure over the drain contact.

18. The method of claim 17, further comprising:
performing a silicidation process to form a silicide region on the front-side surface of the source epitaxial structure.

19. The method of claim 17, further comprising:
performing a silicidation process to form a silicide region on the back-side surface of the drain epitaxial structure.

20. The method of claim 17, further comprising:
doping the source epitaxial structure prior to forming the source contact, such that a dopant concentration of the source epitaxial structure is higher than a dopant concentration of the drain epitaxial structure.
